(19) United States
(12) Patent Application Publication
(10) Pub. No.: US 2013/0199599 A1
(43) Pub. Date: Aug. 8, 2013

(54) POLYESTER FILM, BACK SHEET FOR SOLAR CELL, AND SOLAR CELL MODULE

(71) Applicant: FUJIFILM Corporation, Tokyo (JP)

(72) Inventors: Makoto FUKUDA, Ashigarakami-gun (JP); Seiya SAKURAI, Ashigarakami-gun (JP); Ryuta TAKEGAMI, Ashigarakami-gun (JP); Michihiro OGAWA, Ashigarakami-gun (JP)

(73) Assignee: FUJIFILM CORPORATION, Tokyo (JP)

(21) Appl. No.: 13/799,898

(22) Filed: Mar. 13, 2013

Related U.S. Application Data
(63) Continuation of application No. PCT/JP2011/070259, filed on Sep. 6, 2011.

(30) Foreign Application Priority Data
Sep. 16, 2010 (JP) 2010-208015
May 23, 2011 (JP) 2011-114384

(51) Int. Cl. C08G 63/91; H01L 31/0216

(52) U.S. Cl. CPC C08G 63/916; H01L 31/02167
USPC 136/252; 525/450; 523/400

(57) ABSTRACT

A polyester film containing (A) a polyester, (B) a monofunctional glycidyl ether compound represented by the following general formula, and (C) a reaction promoter can prevent gelation and can reduce vaporization in forming a film, and is excellent in adhesiveness and weather resistance. In the formula, R¹ represents an aliphatic hydrocarbon group, R² and R³ represent an alkylene group, n indicates an integer of 1 or more, and m indicates an integer of 0 or more.

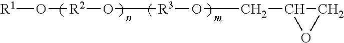

### CROSS-REFERENCE TO RELATED APPLICATIONS

This application is a continuation application of International Application No. PCT/JP2011/070259, filed Sep. 6, 2011, which in turn claims the benefit of priority from Japanese Application No. 2010-208015, filed Sep. 16, 2010, and Japanese Application No. 2011-114384, filed May 23, 2011, the disclosures of which Applications are incorporated by reference herein in their entirety.

### BACKGROUND OF THE INVENTION

1. Field of the Invention

The present invention relates to a polyester film which can prevent gelation and can reduce vaporization in film formation and which is excellent in adhesiveness and weather resistance. The invention also relates to a back sheet for solar cells and a solar cell module using the polyester film.

2. Description of the Related Art

A solar cell module generally has a configuration in which (sealant)/solar cell element/sealant/back sheet (hereinafter this may be referred to as BS) are laminated in that order on glass on which sunlight falls. Concretely, the solar cell element is generally so configured that it is buried in a resin (sealant) such as EVA (ethylene/vinyl acetate copolymer) or the like and BS is stuck thereonto (on the back side relative to the incident light falling thereon). As the back sheet for the solar cell, heretofore used is a polyester film.

However, when an ordinary polyester film is used as a back sheet (BS) for solar cells for a long period of time, it may readily break or peel on the solar cells and, in particular, when left in the environment such as outdoors or the like where it is exposed to weather for a long period of time, it ma readily break or peel.

Accordingly, BS is desired to have good weather resistance (especially hydrolysis resistance). In general, polyester lowers its molecular weight with time through hydrolysis of the ester bond in the molecular chain thereof, therefore causing a problem of weather resistance degradation. As opposed to this, it is known that a weather-resistant polyester film, in which the amount of the terminal carboxyl group (hereinafter referred to as “terminal COOH”) (terminal COOH amount: AV) is relatively lowered so as to increase the hydrolysis resistance of the film, is favorably used for BS (Patent Documents 1-2, 5-6).

As one method for producing a weather-resistant polyester film, there is known a technique of substituting the acid end of the terminal carboxyl group of a polyester with another compound that is referred to as a hydrolysis-resisting agent to thereby resist the hydrolysis of the polyester. It is known to use an epoxy group-containing compound as such a hydrolysis-resisting agent for polyester.

However, in case where such a hydrolysis-resisting agent is mixed in and reacted with a polyester, the hydrolysis-resisting agent may bleed out or may evaporate away in the production process since the melt-forming temperature of the polyester is high, and consequently, when a known hydrolysis-resisting agent is employed, there occurs a problem of fume and odor generation (see PATENT DOCUMENT 1). As opposed to this, PATENT DOCUMENT 2 says that the isocyanurate-type glycidyl ether (or ester) compound in which the glycidyl group is monofunctional to trifunctional, as described therein, can prevent odor generation in producing a weather-resistant polyester resin. However, the paragraph [0005] in PATENT DOCUMENT 1 discloses that, of those compounds described in PATENT DOCUMENT 2, a trifunctional isocyanurate-type glycidyl ether compound of a trifunctional epoxy compound may react with a polyester, therefore also causing a problem of gelation in the production process. From this viewpoint, PATENT DOCUMENT 1 discloses that, when a monofunctional isocyanurate-type glycidyl ether (epoxy compound) is added as a monofunctional epoxy-type hydrolysis-resisting agent, then a polyester resin composition, which is free from a problem of evaporation and gelation in the production process and which can secure good weather resistance and good hydrolysis resistance after forming, can be obtained. However, the evaporation resistance and the hydrolysis resistance are not still sufficient for the recent request level in the art.

On the other hand, in producing a weather-resistant polyester film, there is known a method of further adding a reaction promoter (especially an organic compound-type catalyst) in addition to such an epoxy group-containing hydrolysis-resisting agent.

For example, Patent Documents 3 and 4 have a description relating to a hydrolysis-resistant polyester film using a fatty acid glycerin ester. These patent references say that a hydrolysis-resistant polyester film which is free from a problem of gas generation in production and use thereof can be provided. In the epoxy group-having fatty acid glycerin ester, the epoxy group is polyfunctional because of the production mode thereof. Consequently, the gelation could not be sufficiently prevented and the hydrolysis resistance of the film could not as yet reach the recent request level in the art.

Patent Documents 5 and 6 disclose a large number of glycidyl ethers and glycidyl esters serving as a hydrolysis-resisting agent, specifically exemplifying saturated aliphatic or aromatic monocarboxylic acid diglycidyl esters (especially benzoic acid glycidyl ester or versatic acid glycidyl ester) and aromatic glycidyl ethers (especially bisphenol A diglycidyl ether) as preferred cases therein, and these further disclose a large number of examples of organic catalysts to be combined therewith. As especially preferred examples, there are mentioned alkali or alkaline earth metal salts of organic acids having 6 or more carbon atoms (especially stearic acid or benzoic acid), and these are used in Examples. As other examples than the catalysts of best mode, phosphines (triphenyl phosphate) are used in Examples. Patent Documents 5 and 6 say that these combinations provide polyester compositions excellent in hydrolysis resistance and free from problems of gas generation and viscosity change in melting. However, though catalyst addition could enhance the hydrolysis resistance but could not satisfy both prevention of evaporation and prevention of gelation, and in addition, the hydrolysis resistance could not still reach the recent request level in the art.

Patent Documents 7 to 15 describe a method of adding a monoepoxy compound having a specific structure to polyethylene terephthalate. These patent references say that the addition betters low-temperature formability. However, nothing is described and suggested therein relating to application to films.

### CITATION LIST

PATENT DOCUMENT 1: JP-A 2007-231137
PATENT DOCUMENT 2: JP-A 2007-23444
PATENT DOCUMENT 3: JP-A 2006-77249
PATENT DOCUMENT 4: JP-A 2007-302878
PATENT DOCUMENT 5: JP-A 2007-154210
PATENT DOCUMENT 6: JP-A 2002-220454
PATENT DOCUMENT 7: JP-A 59-157144
PATENT DOCUMENT 8: JP-A 60-96645
PATENT DOCUMENT 9: JP-A 60-130644
PATENT DOCUMENT 10: JP-A 61-18846
PATENT DOCUMENT 11: JP-A 61-181857
PATENT DOCUMENT 12: JP-A 61-213258
PATENT DOCUMENT 13: JP-A 62-96558
PATENT DOCUMENT 14: JP-A 63-238154
PATENT DOCUMENT 15: JP-A 64-24848

### SUMMARY OF THE INVENTION

Given the situation, the present inventors investigated the methods described in Patent Documents 1 to 15, and have known that, when the polyester resin composition described in these references is formed into a film, it is impossible to obtain a formed film of which the hydrolysis resistance is on a high level recently required in the art, while preventing gelation and reducing evaporation. In particular, when the resin composition described in Patent Documents 7 to 15 is directly applied to films, then the formability thereof is good but the hydrolysis resistance thereof is poor, and in addition, the strength thereof is insufficient. In particular, it has been known that, since the strength thereof is insufficient, the obtained polyester films have poor adhesiveness when stuck to solar cell elements and are partly broken, and the solar cell elements may thereby have failures.

The present invention has been made in consideration of the above, and the technical problem which the invention is to solve is to provide a polyester film capable of preventing gelation and reducing evaporation in film formation and excellent in adhesiveness and weather resistance.

The present inventors assiduously studied for the purpose of attaining the above-mentioned object, and have found that, when a monofunctional glycidyl ether compound having a specific structure and a reaction promoter catalyst are combined, then in film formation, the gelation can be prevented more and the evaporation can be reduced more than before, and a polyester film excellent in adhesiveness and weather resistance can be obtained, and have completed the present invention.

Specifically, as the concrete means for solving the above-mentioned problems, the invention includes the following.

[1] A polyester film containing (A) a polyester, (B) a monofunctional glycidyl ether compound represented by the following general formula (1), and (C) a reaction promoter:

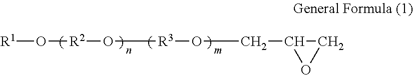

wherein R¹ represents an aliphatic hydrocarbon group having 1 or more carbon atoms, R² and R³ each independently represent an alkylene group having 2 or more carbon atoms provided that R² and R³ differ from each other, n indicates an integer of 1 or more, and m indicates an integer of 0 or more.
[2] The polyester film according to [1], wherein the reaction promoter is a phosphonium compound or a phosphine.
[3] The polyester film according to [1] or [2], wherein n in the general formula (1) is from 2 to 100.
[4] The polyester film according to any one of [1] to [3], wherein R² in the general formula (1) is an ethylene group.
[5] The polyester film according to any one of [1] to [4], wherein R¹ in the general formula (1) is an aliphatic hydrocarbon group having from 8 to 20 carbon atoms.
[6] The polyester film according to any one of [1] to [5], wherein the molecular weight of the monofunctional glycidyl ether compound represented by the general formula (1) is 800 or more.
[7] The polyester film according to any one of [1] to [6], wherein the acid value of the polyester is at most 25 eq/ton.
[8] The polyester film according to any one of [1] to [7], wherein the polyester is polyethylene terephthalate.
[9] The polyester film according to any one of [1] to [8], wherein the polyester is produced through solid-phase polymerization.
[10] A polyester film produced by biaxially stretching the polyester film of any one of [1] to [9].
[11] The polyester film according to any one of [1] to [10], which has an acid value of at most 15 eq/ton.
[12] The polyester film according to any one of [1] to [11], which, when stored in an atmosphere at a temperature of 120° C. and a relative humidity of 100%, takes a storage time of at least 75 hours for which the elongation at break of the film after storage reaches 50% of the elongation at break thereof before storage.
[13] The polyester film according to any one of [1] to [12], which contains a buffer.
[14] The polyester film according to any one of [1] to [13], which is for solar cells.
[15] Aback sheet for solar cells, which contains the polyester film of any one of [1] to [14].
[16] A solar cell power generation module, which contains the polyester film of any one of [1] to [14].

According to the invention, there is provided a polyester film which can prevent gelation and can reduce vaporization in film formation and which is excellent in adhesiveness and weather resistance. There are also provided a back sheet for solar cells using the polyester film of the invention and a solar cell module using it and having long-term durability.

### BRIEF DESCRIPTION OF DRAWINGS

FIG. 1 is a schematic view showing the cross section of one example of the back sheet for solar cells of the invention. 1 is reflection Layer, 2 is easy adhesion layer. 3 is undercoat layer, 4 is barrier layer, 5 is antifouling layer, 5a is first antifouling layer, 5b is second antifouling layer, and 10 is polyester film.

### MODE FOR CARRYING OUT THE INVENTION

The polyester film of the invention and its production method, as well as a back sheet for solar cells and a solar cell module using the film are described in detail hereinunder.

The description of the constitutive elements of the invention given hereinunder is for some typical embodiments of the invention, to which, however, the invention should not be limited. In this description, the numerical range expressed by the wording “a number to another number” means the range that falls between the former number indicating the lower limit of the range and the latter number indicating the upper limit thereof.

### [Polyester Film]

The polyester film of the invention (hereinafter this may be referred to as the film of the invention) contains (A) a polyester, (B) a monofunctional glycidyl ether compound represented by a general formula (1), and (C) a reaction promoter.

### <Monofunctional Glycidyl Ether Compound>

The film of the invention contains a monofunctional glycidyl ether compound represented by a general formula (1).

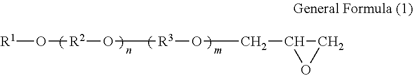

In the formula, R¹ represents an aliphatic hydrocarbon group having 1 or more carbon atoms, R² and R³ each independently represent an alkylene group having 2 or more carbon atoms (provided that R² and R³ differ from each other), n indicates an integer of 1 or more, and m indicates an integer of 0 or more.

The compound having the structure as above differs from the hydrolysis-resisting agent heretofore used in the art in point of the structure thereof, and in particular, differs in that the compound has at least one —(R²—O)n- unit. Having the polyalkylene oxide site, the compound can readily mix with polyester and can effectively react with carboxylic acid, and in addition, since the carbon number of the polyalkylene site is 2 or more, the compound is effective for preventing evaporation of polyester. Further, another characteristic thereof is that the compound has one glycidyl group (the compound is monofunctional). The compound of the type having one glycidyl group in the molecule hardly causes crosslinking when used as an additive to a polyester. Consequently, since the compound is a monofunctional glycidyl ether compound, it can prevent gelation when added to a polyester for film formation.

The monofunctional glycidyl ether compound represented by the general formula (1) is described below.

R¹ represents an aliphatic hydrocarbon group having 1 or more carbon atoms. Preferably, the carbon number of R¹ is from 1 to 30, more preferably from 4 to 25, even more preferably from 8 to 20, still more preferably from 8 to 18, further more preferably from 12 to 18.

Not specifically defined, the aliphatic hydrocarbon group which R¹ can represent may be any known aliphatic hydrocarbon group, including a linear aliphatic hydrocarbon group, a branched aliphatic hydrocarbon group or an alicyclic aliphatic hydrocarbon group. The aliphatic hydrocarbon group may have or may not have an unsaturated bond, but is preferably a saturated aliphatic hydrocarbon group. The aliphatic hydrocarbon group for R¹ is preferably a linear aliphatic saturated hydrocarbon group.

The aliphatic hydrocarbon group preferred for R¹ includes, for example, an alkyl group such as a methyl group, an ethyl group, a propyl group, an isopropyl group, an n-butyl group, a sec-butyl group, a tert-butyl group, a pentyl group, a hexyl group, a heptyl group, an octyl group, a nonyl group, a decyl group, an undecyl group, a lauryl group, a myristyl group, a palmityl group, a stearyl group, etc.; a cycloalkyl group such as a cyclopropyl group, a cyclobutyl group, a cyclopentyl group, a cyclohexyl group, a cycloheptyl group, a cyclooctyl group, a cyclononyl group, a cyclodecyl group, a cycloundecyl group, a cyclododecyl group, etc. Above all, preferred are alkyl groups such as a methyl group, an ethyl group, a propyl group, an isopropyl group, an n-butyl group, a sec-butyl group, a tert-butyl group, a pentyl group, a hexyl group, a heptyl group, an octyl group, a nonyl group, a decyl group, an undecyl group, a lauryl group, a myristyl group, a palmityl group, a stearyl group, etc.; more preferred are a methyl group, an ethyl group, a propyl group, an n-butyl group, a pentyl group, a hexyl group, a heptyl group, an octyl group, a nonyl group, a decyl group, an undecyl group, a lauryl group, a myristyl group, a palmityl group, a stearyl group; and even more preferred are a lauryl group and a stearyl group.

R² and R³ each independently represent an alkylene group having 2 or more carbon atoms (provided that R² and R³ differ from each other). Preferably, the carbon number of R² and R³ is from 2 to 10 each, more preferably from 2 to 4, even more preferably 2 or 3. Especially preferably, these each are an ethylene group having 2 carbon atoms. Not specifically defined, the alkylene group which R² and R³ can represent may be any known aliphatic hydrocarbon group; however, when m is 1 or more, preferably, R² and R³ are an ethylene group and a propylene group. In particular, when m is 0, R² is preferably an ethylene group.

In the above-mentioned general formula (1), n indicates an integer of 1 or more. m in the general formula (1) indicates an integer of 0 or more. Specifically, the compound represented by the general formula (1) has at least one —(R²—O)n- unit. Preferably, (n+m) is from 2 to 100, more preferably from 5 to 30, even more preferably from 8 to 25.

When the degree of polymerization, or that is the value of (n+m) of the polyalkylene oxide sites in the compound represented by the general formula (1) is not more than the upper limit of the preferred range mentioned above, then the epoxy equivalent of the compound is not too large and the compound can sufficiently control carboxylic acid. When the degree of polymerization, or that is the value of (n+m) of the polyalkylene oxide sites in the compound represented by the general formula (1) is not less than the lower limit of the preferred range mentioned above, then the compound is effective for preventing evaporation of polyester.

In case where the compound represented by the general formula (1) is a copolymer, it may be a block copolymer or a random copolymer, but is more preferably a block copolymer. In case where the compound represented by the general formula (1) is a copolymer, preferably, n and m each are independently from 1 to 50, more preferably from 3 to 15, even more preferably from 4 to 12.

On the other hand, more preferably, m is 0, or that is, the compound represented by the general formula (1) is more preferably a homopolymer of —(R²—O)n- units.

More preferably, the monofunctional glycidyl ether compound represented by the general formula (1) is represented by the following general formula (2) or (3).

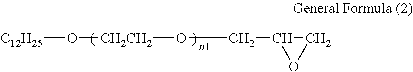

In the formula, n1 indicates an integer of 1 or more.

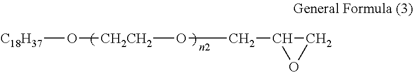

In the formula, n2 indicates an integer of 1 or more.

When the molecular weight of the monofunctional glycidyl ether compound represented by the general formula (1) is not less than the lower limit of the preferred range to be mentioned below, then the compound can fully solve the problem of evaporation. When the molecular weight of the monofunctional glycidyl ether compound represented by the general formula (1) is not more than the upper limit of the preferred range to be mentioned below, then the epoxy equivalent of the compound is not too small and the compound can fully exhibit the effect thereof, and another advantage thereof is that the amount of the compound to be added can be reduced and the film production cost can be therefore reduced. Concretely, the molecular weight of the compound is preferably at least 800, more preferably from 800 to 2000, even more preferably from 800 to 1500.

In the general formula (2), when n1 is 14 or more, then the molecular weight of the compound is at least 800. Specifically, in the general formula (2), n1 is preferably from 14 to 50, more preferably from 14 to 30, even more preferably from 15 to 25.

On the other hand, in the general formula (3), when n2 is 11 or more, then the molecular weight of the compound is at least 800. Specifically, in the general formula (3), n2 is preferably from 11 to 50, more preferably from 11 to 30, even more preferably from 11 to 25.

Regarding the amount to be added of the monofunctional glycidyl ether compound represented by the general formula (1), when the amount is too small, the compound could hardly exhibit its effect, and when the amount is not more than the preferred range to be mentioned below, then the compound hardly causes problem of plasticization or bleeding. In the polyester film of the present invention, the amount of the compound is preferably from 0.01 to 10% by mass of the polyester therein, more preferably from 0.1 to 8% by mass, even more preferably from 0.5 to 5% by mass, still more preferably from 1 to 5% by mass. When the amount falls within the range, the compound can efficiently reduce the acid value of the polyester film of the invention and can efficiently enhance the weather resistance thereof.

### <Reaction Promoter>

The polyester film of the invention contains a reaction promoter. In the invention, combining the monofunctional glycidyl ether compound represented by the general formula (1) and a reaction promoter can greatly and effectively reduce the acid value of the polyester film to be obtained from the acid value of the starting polyester. As a result, the weather resistance of the polyester film of the invention, which is obtained from the polyester resin composition containing the monofunctional glycidyl ether compound represented by the general formula (1) and a reaction promoter, can be thereby enhanced.

The reaction promoter that can be preferably used here along with the monofunctional glycidyl ether compound represented by the general formula (1) in the invention is described below.

As the reaction promoter, preferred is use of imidazole compounds, phosphines, phosphonium compounds, sulfonium compounds, ammonium compounds and the like, to which, however, the invention is not limited. Not overstepping the spirit and the scope of the invention, any other reaction promoter is usable here.

### (Imidazole)

The imidazole compound includes, for example, imidazole, 2-methylimidazole, 2-ethyl-4-methylimidazole, 2-phenylimidazole, 2-undecylimidazole, 2-heptadecylimidazole, 1-benzyl-2-methylimidazole, 2-phenyl-4-methylimidazole, 1-cyanoethyl-2-methylimidazole, 1-cyanoethyl-2-phenylimidazole, 1-cyanoethyl-2-phenyl-4-methylimidazole, 2-methylimidazole/isocyanuric acid adduct, 2-phenylimidazole/isocyanuric acid adduct, etc. Above all, those having a large molecular weight are preferred, and 2-undecylimidazole and 2-heptadecylimidazole are preferred.

### (Phosphonium Salt)

The phosphonium salt includes tetra-alkylphosphonium salts and triarylphosphonium salts.

The tetra-alkylphosphonium salt is a compound that contains a structure with four alkyl groups bonding to a phosphorus atom, in which the phosphorus atom is a positively-charged cation and which has a negatively-charged anion as the counter ion. The alkyl group in the tetra-alkyl phosphonium salt may have any structure of a linear structure, a branched structure or a cyclic structure. All these four alkyl groups may have the same structure, or each may have a different structure. The carbon number of the alkyl group is preferably at most 30, more preferably at most 20. Concretely, the tetra-alkyl phosphonium salt includes compounds represented by the following general formula (4).

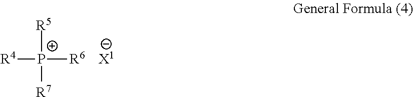

In the general formula (4), R⁴ to R⁷ each independently represent an alkyl group, and X¹ represents a halogen atom. The alkyl group represented by R⁴ to R⁷ is as mentioned above. The halogen atom includes a fluorine atom, a chlorine atom, a bromine atom and an iodine atom. Above all, preferred are a chlorine atom, a bromine atom and an iodine atom.

Specific examples of the tetra-alkylphosphonium salt represented by the general formula (4) include tetraethylphosphonium chloride, tetraethylphosphonium bromide, tetraethylphosphonium iodide; tetrabutylphosphonium chloride, tetrabutylphosphonium bromide, tetrabutylphosphonium iodide; tetra-octylphosphonium chloride, tetra-octylphosphonium bromide, tetra-octylphosphonium iodide; tributylmethylphosphonium chloride, tributylmethylphosphonium bromide, tributylmethylphosphonium iodide; tributyloctylphosphonium chloride, tributyloctylphosphonium bromide, tributyloctylphosphonium iodide; tributyldodecylphosphonium chloride, tributyldodecylphosphonium bromide, tributyldodecylphosphonium iodide; tributylhexadecylphosphonium chloride, tributylhexadecylphosphonium bromide, tributylhexadecylphosphonium iodide, etc.

The triarylphosphonium salt contains a structure with three aryl groups bonding to a phosphorus atom, preferably having a hydrogen atom or a substituent such as an alkyl group, an alkoxy group, an aryl group or the like bonding to the phosphorus atom. To the aryl group bonding to the phosphorus atom, an alkyl group, an alkoxy group or a phenyl group may further bond. The aryl group in the triarylphosphonium salt includes a phenyl group, a naphthalene group, a biphenyl group. Above all, preferred is a phenyl group.

The phosphorus atom in the triarylphosphonium salt is a positively-charged cation, and the salt has a negatively-charged anion as the counter ion therein. The triarylphosphonium salt includes compounds having a structure represented by a general formula (5).

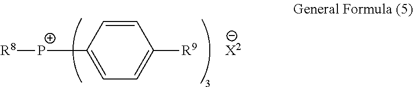

In the general formula (5), R⁸ represents an alkyl group, an alkoxy group or a phenyl group, R⁹ represents an alkyl group, X² represents a halogen atom. The alkyl group for R⁸ may have any structure of a linear structure, a branched structure or a cyclic structure. The carbon number of the alkyl group is preferably at most 30, more preferably at most 20. The carbon number of the alkoxy group for R⁸ is preferably at most 30, more preferably at most 20. The carbon number of the alkyl group for R⁹ is preferably at most 30, more preferably at most 20. The halogen atom for X² includes a fluorine atom, a chlorine atom, a bromine atom and an iodine atom. Preferred are a chlorine atom, a bromine atom and an iodine atom.

Specific examples of the triarylphosphonium salt having the structure represented by the general formula (5) includes, for example, methyltriphenylphosphonium chloride, methyltriphenylphosphonium bromide, methyltriphenylphosphonium iodide; ethyltriphenylphosphonium chloride, ethyltriphenylphosphonium bromide, ethyltriphenylphosphonium iodide; propyltriphenylphosphonium chloride, propyltriphenylphosphonium bromide, propyltriphenylphosphonium iodide, isopropyltriphenylphosphonium iodide; butyltriphenylphosphonium chloride, butyltriphenylphosphonium bromide, butyltriphenylphosphonium iodide; hexyltriphenylphosphonium chloride, hexyltriphenylphosphonium bromide, hexyltriphenylphosphonium iodide; heptyltriphenylphosphonium chloride, heptyltriphenylphosphonium bromide, heptyltriphenylphosphonium iodide; octyltriphenylphosphonium chloride, octyltriphenylphosphonium bromide, octyltriphenylphosphonium iodide; octyltriphenylphosphonium chloride, octyltriphenylphosphonium bromide, octyltriphenylphosphonium iodide; tetradecylphosphonium chloride, tetradecylphosphonium bromide, tetradecylphosphonium iodide, etc.

Of those, preferred are butyltriphenylphosphonium bromide, hexyltriphenylphosphonium bromide, heptyltriphenylphosphonium bromide, and tetradecyltriphenylphosphonium bromide.

Of those, preferred are tetra-octylphosphonium bromide, tributyloctylphosphonium bromide, tributyldodecylphosphonium bromide, tributylhexadecylphosphonium bromide.

### (Phosphine)

As the phosphone, preferred is a triaryl phosphine structure having a substituent, in which the aryl group bonding to the phosphorus atom includes a phenyl group, a naphthalene group and a biphenyl group. Above all, preferred is a phenyl group. The substituent that the aryl group has includes an alkyl group, an alkoxy group and a phenyl group.

The triaryl phosphine having a substituent concretely includes compounds having a structure represented by the following general formula (6).

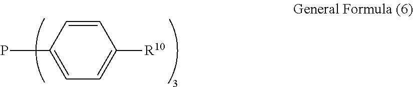

In the general formula (6), R¹⁰ represents a hydrogen atom, an alkyl group, an alkoxy group or a phenyl group. The alkyl group represented by R¹⁰ may have any structure of a linear structure, a branched structure or a cyclic structure. The carbon number of the alkyl group is preferably at most 30, more preferably at most 20. The carbon number of the alkoxy group represented by R¹⁰ is preferably at most 30, more preferably at most 20.

Specific examples of the phosphine having a substituent and having the structure represented by the general formula (6) include, for example, triphenyl phosphine, tris(4-methylphenyl)phosphine, tris(4-ethylphenyl)phosphine, tris(4-propylphenyl)phosphine, tris(4-butylphenyl)phosphine, tris(4-methoxyphenyl)phosphine, tris(4-ethoxyphenyl)phosphine, tris(4-propoxyphenyl)phosphine, tris(4-butoxyphenyl)phosphine, etc. Of those, preferred are triphenyl phosphine, tris(4-methylphenyl)phosphine, tris(4-methoxyphenyl)phosphine.

### (Sulfonium Salt)

The sulfonium salt includes triarylsulfonium salts such as triphenylsulfonium tetrafluoroborate, triphenylsulfonium hexafluorophosphate, p-(phenylthio)phenyldiphenylsulfonium hexafluoroantimonate, triphenylsulfonium hexafluoroantimonate, 4-chlorophenyldiphenylsulfonium hexafluorophosphate, etc.; and diphenylsulfonium hexafluoroantimonate, dialkylphenylsulfonium hexafluoroantimonate, dialkylphenylsulfonium hexafluorophosphate, 4,4-bis[di-(β-hydroxyethoxy)phenylsulfonio]phenylsulfide bis-hexafluoroantimonate, 4,4-bis[di(β-hydroxyethoxy)phenylsulfonio]phenylsulfide bis-hexafluorophosphate, etc.

### (Ammonium Salt)

The ammonium salt is preferably one having a large molecular weight, and more preferred is an aliphatic ammonium salt. The aliphatic ammonium salt includes salts of a higher aliphatic ammonium such as lauryltrimethylammonium, stearyltrimethylammonium, cetyltrimethylammonium, didecyldimethylammonium, benzylmethyltetradecylammonium or the like, with chloride, bromide or the like. Concretely, for example, there are mentioned lauryltrimethylammonium chloride, stearyltrimethylammonium chloride, cetyltrimethylammonium chloride, didecyldimethylammonium chloride, benzyldimethyltetradecylammonium chloride, lauryltrimethylammonium bromide, stearyltrimethylammonium bromide, cetyltrimethylammonium bromide, didecyldimethylammonium bromide, benzyldimethyltetradecylammonium bromide, etc.

As the reaction promoter, preferred are the phosphonium compounds or the phosphines of the above-mentioned compounds, from the viewpoint of the reactivity and the non-volatility thereof.

The reaction promoter is added to the polyester film of the invention in an amount of from 0.001 to 1% by mass of the polyester constituting the film, more preferably in an amount of from more than 0.01% by mass to 0.5% by mass, even more preferably from 0.01 to 0.15% by mass. When the amount falls within the range, the acid value of the polyester film of the invention can be efficiently reduced and the weather resistance thereof can be efficiently enhanced.

### <Polyester>

The polyester for use in the polyester film of the invention may be obtained according to a well-known method of esterification and/or interesterification of (A) a dicarboxylic acid, for example, an aliphatic dicarboxylic acid such as malonic acid, succinic acid, glutaric acid, adipic acid, suberic acid, sebacic acid, dodecanedioic acid, dimer acid, eicosanedioic acid, pimelic acid, azelaic acid, methylmalonic acid, ethylmalonic acid or the like, an alicyclic dicarboxylic acid such as adamantane-dicarboxylic acid, norbornene-dicarboxylic acid, isosorbide, cyclohexane-dicarboxylic acid, decalin-dicarboxylic acid or the like, or an aromatic dicarboxylic acid such as terephthalic acid, isophthalic acid, phthalic acid, 1,4-naphthalene-dicarboxylic acid, 1,5-naphthalene-dicarboxylic acid, 2,6-naphthalene-dicarboxylic acid, 1,8-naphthalene-dicarboxylic acid, 4,4′-diphenyldicarboxylic acid, 4,4′-diphenylether-dicarboxylic acid, 5-sodium sulfoisophthalic acid, phenylendane-dicarboxylic acid, anthracene-dicarboxylic acid, phenanthrenedicarboxylic acid, 9,9′-bis(4-carboxyphenyl)fluorenic acid or the like, or an ester derivative thereof, with (B) a diol compound, for example, an aliphatic diol such as ethylene glycol, 1,2-propanediol, 1,3-propanediol, 1,4-butanediol, 1,2-butanediol, 1,3-butanediol or the like, an alicyclic diol such as cyclohexanedimethanol, spiroglycol, isosorbide or the like, or an aromatic diol such as bisphenol A, 1,3-benzenedimethanol, 1,4-benzenedimethanol, 9,9′-bis(4-hydroxyphenyl)fluorene or the like.

Preferably, at least one aromatic dicarboxylic acid is used as the dicarboxylic acid component. More preferably, the dicarboxylic acid component contains an aromatic dicarboxylic acid as the main ingredient thereof. “Main ingredient” means that an aromatic dicarboxylic acid occupies at least 80% by mass of the dicarboxylic acid component. The dicarboxylic acid component may contain any other dicarboxylic acid than the aromatic dicarboxylic acid therein. The additional dicarboxylic acid component includes ester derivatives of aromatic dicarboxylic acids.

Preferably, at least one aliphatic diol is used as the diol component. The diol component may contain ethylene glycol as the aliphatic diol therein, and preferably contains ethylene glycol as the main ingredient thereof. “Main ingredient” means that ethylene glycol occupies at least 80% by mass of the diol component.

Preferably, the amount of the aliphatic diol (for example, ethylene glycol) to be used is within a range of from 1.015 to 1.50 mols relative to one mol of the aromatic dicarboxylic acid (for example, terephthalic acid) and optionally its ester derivative. The amount to be used is more preferably from 1.02 to 1.30 mols, even more preferably from 1.025 to 1.10 mols. When the amount to be used is at least 1.015 mols, then the esterification may go on well; and when at most 1.50 mols, for example, ethylene glycol may be prevented from being dimerized to give a side product, diethylene glycol, and consequently, the resulting polyester can maintain good melting point and glass transition temperature and can have may other good properties of crystallinity, heat resistance, hydrolysis resistance, weather resistance, etc.

Of the above, more preferred polyesters are polyethylene terephthalate (PET) and polyethylene 2,6-naphthalate (PEN), and even more preferred is PET.

Preferably, PET contains terephthalic acid and ethylene glycol in an amount of at least 90 mol %, more preferably at least 95 mol %, even more preferably at least 98 mol %.

### (Amount of Terminal Carboxyl Group, AV, of Polyester)

Of the starting polyester for use in the polyester film of the invention, the amount of the terminal carboxyl group (hereinafter this may be referred to as “terminal COOH”) (amount of terminal COOH: AV) is preferably at most 25 eq/ton. The terminal carboxylic acid has strong interaction between the polyester molecules, and therefore a high value of AV promotes aggregation of polyester molecules. In the invention, preferably, AV in the polyester is relatively small.

The terminal COOH amount is more preferably from 6 eq/ton to 24 eq/ton, even more preferably from 7 eq/ton to 22 eq/ton.

The terminal COOH amount is determined as follows: The polyester is completely dissolved in a mixed solution of benzyl alcohol/chloroform (=2/3 by volume), and using phenol red as an indicator, the resulting solution is titered with a standard solution (0.025 N KOH/methanol mixed solution), and the terminal COOH amount is derived from the titered value through computation.

The polyester may be obtained through synthesis and polymerization, or may be a commercially-available one.

The polyester may be controlled to have the intended AV as above through solid-phase polymerization or by increasing the vacuum degree during polymerization to thereby prevent oxidation by residual oxygen.

Preferably, the solid-phase polymerization is carried out in a desired case from the viewpoint of more lowering the terminal COOH amount or from the viewpoint of increasing the molecular weight of the polyester. A preferred embodiment of the solid-phase polymerization is described in the section of the preferred production method for the polyester film of the invention to be given below.

### (Other Characteristics of Polyester Resin Composition, and Additives)

The absorbance can be controlled by adding an organic or inorganic UV absorbent, however, from the viewpoint of maintaining the resistance for a long period of time, it is desirable to use an inorganic UV absorbent. As the UV absorbent, there are mentioned the same as those described in the section of the additives given below. Above all, TiO2 is more preferred as the UV absorbent. The preferred amount of the UV absorbent to be added is from 0.01% by mass to 5% by mass relative to polyester, more preferably from 0.1% by mass to 3% by mass, even more preferably from 0.3% by mass to 3% by mass.

Preferably, the polyester film of the invention is obtained by using a titanium compound as the catalyst. As compared with any other catalyst (Sb, Ge, Al) than titanium compounds, the amount of the titanium compound to be added may be small, and therefore the formation of spheres around the catalyst nuclei can be prevented. The details of the titanium compound are described in the section of the production method for polyester film to be given below.

In case where the polyester film is produced by the use of a titanium compound, the titanium catalyst is added to the polyester resin composition in such a controlled manner that the titanium atom could remain in the film in an amount of from 1 ppm to 30 ppm.

The polyester film of the invention may further contain additives such as light stabilizer, antioxidant, buffer, polyfunctional capping agent, etc.

Preferably, the polyester film of the invention contains a light stabilizer. Containing a light stabilizer, the film can be prevented from being degraded by UV rays. The light stabilizer includes compounds capable of absorbing light such as UV rays and the like to convert it into heat energy, and materials capable of trapping the radical generated through light absorption and decomposition of films and others, thereby to inhibit decomposition chain reaction, etc.

As the light stabilizer, preferred are compounds capable of absorbing light such as UV rays and the like to convert it into heat energy. Containing the light stabilizer of the type, the film can keep high the effect of increasing the partial discharge voltage of the film for a long period of time, even when continuously irradiated with UV rays for a long period of time, and consequently, the film can be prevented from discoloration and strength degradation through exposure to UV rays. For example, any of an organic UV absorbent or an inorganic UV absorbent or even a combination of the two may be favorably used here with no specific limitation thereon within a range not detracting from the characteristics of the polyester for use in the invention. On the other hand, it is desirable that the UV absorbent is excellent in wet heat resistance and is uniformly dispersed in the film of the invention.

Examples of the UV absorbent are described. The organic UV absorbent includes salicylate-type, benzophenone-type, benzotriazole-type, cyanoacrylate-type and the like UV absorbents, and hindered amine-type and the like UV stabilizers. Concretely, for example, there are mentioned salicylate-type p-t-butylphenyl salicylate, and p-octylphenyl salicylate; benzophenone-type 2,4-dihydroxybenzophenone, 2-hydroxy-4-methoxybenzophenone, 2-hydroxy-4-methoxy-5-sulfobenzophenone, 2,2′,4,4′-tetrahydroxybenzophenone, and bis(2-methoxy-4-hydroxy-5-benzoylphenyl)methane; benzotriazole-type 2-(2′-hydroxy-5′-methylphenyl)benzotriazole, 2-(2′-hydroxy-5′-methylphenyl)benzotriazole, and 2,2′-methylenebis[4-(1,1,3,3-tetramethylbutyl)-6-(2H-benzotriazol-2-yl)phenol]; cyanoacrylate-type ethyl-2-cyano-3,3′-diphenyl acrylate; triazine-type 2-(4,6-diphenyl-1,3,5-triazin-2-yl)-5-[(hexyl)oxy]phenol; hindered amine-type bis(2,2,6,6-tetramethyl-4-piperidyl)sebacate, dimethyl succinate/1-(2-hydroxyethyl)-4-hydroxy-2,2,6,6-tetramethylpiperidine polycondensate; and others of nickelbis(octylphenyl)sulfide, 2,4-di-t-butylphenyl 3′,5′-di-t-butyl-4′-hydroxybenzoate, etc.

Of those UV absorbents, more preferred are triazine-type UV absorbents as highly resistant to repeated UV absorption. The UV absorbent may be added to the film as a single substance thereof, or may be added thereto in the form of copolymerization of an organic electroconductive material or a water-insoluble resin with a UV-absorbing monomer.

Preferably, the content of the light stabilizer is controlled to be from 0.1% by mass to 10% by mass relative to the total mass of the polyester film, more preferably from 0.3% by mass to 7% by mass, even more preferably from 0.7% by mass to 4% by mass. Accordingly, the molecular weight of the polyester can be prevented from lowering owing to photodegradation with long-term aging and, as a result, the adhesion power of the film can be prevented from lowering owing to cohesion failure inside the film.

### (Buffer)

Preferably, the polyester film of the invention contains a buffer. The polyester film of the invention may be a single-layer film or a multilayer film, but preferably contains a buffer in at least one polyester layer thereof that comprises at least the above-mentioned polyester as the main ingredient thereof (hereinafter the polyester layer is referred to as P layer), and preferably, the P layer contains a buffer in an amount of from 0.1 mol/t to 5.0 mol/t. The amount of the buffer to be in the polyester film of the invention is preferably from 0.002 to 0.1% by mass of the polyester in the film.

The buffer to be added to the polyester film is a substance that is soluble in the diol constitutive component (for example, ethylene glycol or the like) that constitutes the polyester of the polyester film of the invention and, after dissolved therein, can dissociate to be ionic. In case where the polyester film of the invention contains a buffer (preferably in the P layer thereof), the number of the initial terminal carboxyl groups of the starting polyester can be reduced more and therefore, in the polyester film of the invention, the polyester can be prevented from being hydrolyzed before film formation, or during film formation or after film formation. In addition, the starting polyester can also be prevented from being hydrolyzed, and more precisely, the proton of the terminal carboxyl group that is newly generated through hydrolysis of the polyester can be neutralized by the proton, whereby the hydrolysis of the polyester can be prevented more efficiently. As a result, the polyester film of the invention can be protected from wet heat degradation more efficiently.

Not specifically defined, the buffer for use in the polyester film of the invention may be any known buffer not contradictory to the spirit and the scope of the invention

Regarding specific examples of the buffer, the buffer preferably contains an alkali metal salt from the viewpoint of the polymerization reactivity and the wet heat resistance thereof, and the alkali metal salt includes, for example, alkali metal salts of a compound such as phthalic acid, citric acid, carbonic acid, lactic acid, tartaric acid, phosphoric acid, phosphorous acid, hypophosphorous acid, polyacrylic acid or the like and an alkali metal. The compound to form the alkali metal salt with an alkali metal is preferably a weak acid.

Of the alkali metal salts, preferred are those containing potassium or sodium as the alkali metal element therein from the viewpoint that the catalyst residue hardly form a precipitate. More preferably, the alkali metal salts contain any one alone of potassium or sodium. Even more preferably, the alkali metal element is sodium or potassium. Concretely, the buffer includes potassium hydrogenphthalate, sodium dihydrogencitrate, disodium hydrogencitrate, potassium dihydrogencitrate, dipotassium hydrogencitrate, sodium carbonate, sodium tartrate, potassium tartrate, sodium lactate, potassium lactate, sodium hydrogencarbonate, disodium hydrogenphosphate, Dipotassium hydrogenphosphate, potassium dihydrogenphosphate, sodium dihydrogenphosphate, sodium hydrogenphosphite, potassium hydrogenphosphite, sodium hypophosphite, potassium hypophosphite, sodium polyacrylate, etc. Of those, preferred is sodium dihydrogenphosphate.

Preferably, the buffer contains a weak acid to form the above-mentioned alkali metal salt, along with the alkali metal salt therein. More preferably, the buffer contains sodium dihydrogenphosphate and phosphoric acid, and even more preferably the buffer is comprised of sodium dihydrogenphosphate and phosphoric acid.

### (Polyfunctional Capping Agent)

The monofunctional glycidyl ether compound may be combined with a polyfunctional capping agent. The amount of the agent to be added is preferably within a range not causing gelation. More preferably, the amount is from 0.01% to 1%. The functional group of the polyfunctional capping agent includes epoxy, oxazoline, carbodiimide, isocyanate.

As the polyfunctional carbodiimide compound, preferred is a carbodiimide having a degree of polymerization of from 3 to 15. Concretely, there are mentioned 1,5-naphthalenecarbodiimide, 4,4′-diphenylmethanecarbodiimide, 4,4′-diphenyldimethylmethanecarbodiimide, 1,3-phenylenecarbodiimide, 1,4-phenylene diisocyanate, 2,4-tolylenecarbodiimide, 2,6-tolylenecarbodiimide, mixture of 2,4-tolylenecarbodiimide and 2,6-tolylenecarbodiimide, hexamethylenecarbodiimide, cyclohexane-1,4-carbodiimide, xylylenecarbodiimide, isophoronecarbodiimide, isophoronecarbodiimide, dicyclohexylmethane-4,4′-carbodiimide, methylcyclohexanecarbodiimide, tetramethylxylylenecarbodiimide, 2,6-diisopropylphenylcarbodiimide, 1,5-diisopropylbenzene-2,4-polycarbodiimide and 1,3,5-triisopropylbenzene-2,4-carbodiimide.

Carbodiimide compounds generate isocyanate gas through thermal decomposition, and therefore carbodiimide compounds having high heat resistance are preferred here. For increasing the heat resistance thereof, carbodiimide compounds having a larger molecular weight (having a higher degree of polymerization) are preferred, and carbodiimide compounds of which the terminal structure has high heat resistance are more preferred. When once thermally decomposed, carbodiimide compounds may be further thermally decomposed with ease, and therefore, require some method of lowering the extrusion temperature of polyester, etc.

Preferred examples of polyfunctional capping agents with which the above-mentioned carbodiimide compounds are capped include Stabaxol P-100 (by Rhein Chemie, mixture of poly(1,3,5-triisopropylbenzene-2,4-carbodiimide) and poly(1,5-diisopropylbenzene-2,4-polycarbodiimide), etc.

The polyfunctional oxazoline compound includes 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline), 2,2′-bis(4-cyclohexyl-2-oxazoline), 2,2′-bis(4-benzyl-2-oxazoline), 2,2′-p-phenylenebis(2-oxazoline), 2,2′-m-phenylenebis(2-oxazoline), 2,2′-o-phenylenebis(2-oxazoline), 2,2′-p-phenylenebis(4-methyl-2-oxazoline), 2,2′-p-phenylenebis(4,4-dimethyl-2-oxazoline), 2,2′-m-phenylenebis(4-methyl-2-oxazoline), 2,2′-m-phenylenebis(4,4-dimethyl-2-oxazoline), 2,2′-ethylenebis(2-oxazoline), 2,2′-tetramethylenebis(2-oxazoline), 2,2′-hexamethylenebis(2-oxazoline), 2,2′-octamethylenebis(2-oxazoline), 2,2′-decamethylenebis(2-oxazoline), 2,2′-ethylenebis(4-methyl-2-oxazoline), 2,2′-tetramethylenebis(4,4-dimethyl-2-oxazoline), 2,2′-9,9′-diphenoxyethanebis(2-oxazoline), 2,2′-cyclohexylenebis(2-oxazoline), 2,2′-diphenylenebis(2-oxazoline), etc. Of those, most preferred is 2,2′-bis(2-oxazoline) from the viewpoint of the reactivity thereof with polyester.

Also preferably, the polyfunctional oxazoline compound is a polymer, and the degree of polymerization thereof is not specifically defined. In case where the polyfunctional oxazoline compound is a polymer, more preferably, the compound is a copolymer that has any other partial structure not having an oxazoline group in addition to the partial structure having an oxazoline group.

Preferred examples of the polyfunctional capping agent with which the above-mentioned polyfunctional oxazoline compounds are capped include Epocross RPS-1005 (by Nippon Shokubai, styrene-vinyloxazoline copolymer), etc.

The polyfunctional epoxy compound is preferably a bifunctional epoxy compound prepared by adding epichlorohydrin to the alcohol group at both ends of a diol having an alcohol at both ends thereof. Concretely, diols with alcohol groups include bisphenol A, polyethylene glycol, polypropylene glycol, etc.

Specific examples of the polyfunctional capping agent with which the above-mentioned polyfunctional epoxy compounds are capped include EPICLON 860 (Compound (14) to be mentioned below, by DIC, bisphenol A diglycidyl ether), etc.

Further, the polyester film of the invention may contain, for example, a lubricant (fine particles), a colorant, a heat stabilizer, a nucleating agent (a crystallizing agent), a flame retardant and the like as additives.

Before the polyester resin is melt-extruded, inorganic fine particles may be added to the polyester resin composition. The inorganic fine particles include, for example, silica, alumina, titania, zirconia, talc, calcium carbonate, kaolin, layered mica, barium sulfate, aluminium hydroxide, zinc oxide, barium sulfate, calcium phosphate, etc. Of those, preferred is calcium phosphate which is excellent in lubricity and has good adhesiveness to resin and therefore hardly peels off in long-term use.

In case where calcium phosphate is added, its amount to be added is preferably from 20 to 500 ppm in terms of ratio by weight to the polyester resin, more preferably from 50 to 250 ppm, even more preferably from 70 to 200 ppm.

### <Film Characteristics>

The polyester film of the invention is excellent in hydrolysis resistance. In addition, the film of the invention is free from a problem of gelation in producing it, and is also free from a problem of evaporation during film formation. Other advantages of the film of the invention are that the film is free from these problems. Further, though the COOH content therein is small, the adhesiveness of the film is kept good as the wettability of the polyester in the film is bettered.

The characteristics of the polyester film of the invention are described below.

### (Amount of Terminal Carboxyl Group, AV)

In the polyester film of the invention, preferably, the amount of the terminal carboxyl group (hereinafter this may be referred to as “terminal COOH”) (amount of terminal COOH: AV) in the polyester resin is at most 15 eq/ton. The terminal carboxylic acid has strong interaction between polyester resin molecules, and therefore, when AV is high, then the polyester resin molecules readily aggregate. In the invention, preferably, AV in the polyester resin is relatively small. One advantage that AV is controlled to fall within the range is that the hydrolysis of the polyester is retarded and the weather resistance of the film is thereby bettered.

More preferably, the amount of terminal COOH in the polyester film of the invention is from 6 eq/ton to 15 eq/ton, even more preferably from 6 eq/ton to 13 eq/ton.

The terminal COOH amount is determined as follows: The polyester is completely dissolved in a mixed solution of benzyl alcohol/chloroform (=2/3 by volume), and using phenol red as an indicator, the resulting solution is titered with a standard solution (0.025 N KOH/methanol mixed solution), and the terminal COOH amount is derived from the titered value through computation.

### (Half-Life Period of Elongation at Break)

When heat-treated in an atmosphere at a temperature of 120° C. and a relative humidity of 100%, the weather-resistant polyester film of the invention preferably takes a heat treatment time of at least 75 hours for which the elongation at break of the film after the heat treatment reaches 50% of the elongation at break thereof before the heat treatment (the heat treatment time may be hereinafter referred to as half-life period of elongation at break, and this means a half-life period of elongation at break).

The polyester film of the invention contains the monofunctional glycidyl ether compound represented by the above-mentioned general formula (1), and therefore its weather resistance is thereby bettered and the half-life period of elongation at break thereof can be 75 hours or more. Preferably, the half-life period of elongation at break is from 75 to 150 hours, more preferably from 80 to 150 hours, even more preferably from 85 to 150 hours, still more preferably from 90 to 150 hours. When the half-life period of elongation at break is not lower than the lower limit, then the film may be prevented in some degree from being degraded with time when used outdoors in solar cells.

The hydrolysis resistance of the film may also be evaluated based on the half-life period of elongation at break, as follows: The film is forcedly hydrolyzed through heat treatment at 120° C. and at a relative humidity of 100% (hereinafter this may be referred to as thermotreatment), and from the reduction in the elongation at break of the thus-treated film, the hydrolysis resistance thereof may be determined. The concrete measurement method is described below.

In the invention, the half-life period of elongation at break is the heat treatment time [hr] for which the retention of elongation at break of the film after heat treated at 120° C. and at a relative humidity of 100% (thermotreatment) is within a range of at least 50%. The retention of elongation at break is determined according to the following formula (1).

Retention of Elongation at Break [%]=[(elongation at break after thermotreatment)/(elongation at break before thermotreatment)]×100 (1)

Concretely, a sample of the film is heat-treated (thermotreated) for from 10 hours to 300 hours at 120° C. and at a relative humidity of 100% at time intervals of 10 hours, and then the elongation at break of each thermotreated sample is measured. The measured value is divided by the elongation at break before thermotreatment, and the retention of elongation at break of each sample at a different thermotreatment time is obtained. On a graph of which the horizontal axis indicates a thermotreatment time and the vertical axis indicates the retention of elongation at break, the data are plotted, and these are connected to give a line, on which the heat treatment time to give a retention of elongation at break of at least 50% is read.

The elongation at break of the polyester film is as follows: A sample of the film is set on a tensile tester, and in an environment at 25° C. and at a relative humidity of 60%, the sample is pulled at a rate of 20 mm/min, and the time before the sample is broken is recorded. The sample is divided into 10 equal parts in the width of the MD direction and the TD direction, and at each point, and the test is repeated five times at intervals of 20 cm, or that is, 50 points of each one sample are analyzed. The found data are averaged to give the elongation at break of the tested sample.

### (Thickness)

Preferably, the thickness of the film of the invention is from 30 μm to 500 μm, more preferably from 40 μm to 400 μm, even more preferably from 45 μm to 360 μm, still more preferably from 80 to 280 μm. In case where the polyester film of the invention is used as a back sheet for solar cells, the film is preferably thicker, and especially when any other resin film is not laminated on the film for use as a back sheet for solar cells, it is especially preferable that the film is thicker.

### (Layer Configuration)

The film of the invention may be a single-layer polyester film.

The film of the invention may also be a multilayer laminate with any other film, and in such a case, the laminate may comprise the polyester film containing the monofunctional glycidyl ether compound represented by the general formula (1) and the reaction promoter mentioned above and, in addition thereto, any other polyester film or any other resin film.

Above all, the film of the invention is preferably one that contains one alone of the polyester film that contains the monofunctional glycidyl ether compound represented by the general formula (1) and the reaction promoter defined in the invention.

On the other hand, it is desirable that the film having a thickness of from 30 μm to 200 μm is, when used as a back sheet for solar cells, stuck to any other film for attaining the necessary electric strength to have a thickness of from 100 μm to 500 μm. The other film to which the film of the invention is stuck is preferably a fluororesin film, a polyester film, an Si resin film, a polyolefinic film, a vinyl alcohol film, etc.

The film of the invention may additionally have any functional layer apart from the resin film such as a polyester film or the like. The functional layer is described in the section of the back sheet for solar cells of the invention to be given below. Above all, it is desirable that the film of the invention has an embodiment where at least any one of an easy adhesion layer and a colorant layer (preferably a white layer (reflection layer)) is laminated on the polyester film. More preferably, an easy adhesion layer and a white layer (reflection layer) are laminated on both surfaces of the polyester film, and even more preferably, an easy adhesion layer and a white layer (reflection layer) are laminated on both surfaces of the polyester film by coating.

### <Production Method for Polyester Film>

The polyester film of the invention may be produced according to the production method mentioned below. However, the invention is not limited to the following embodiment.

One example of the production method for the polyester film of the invention comprises a step of preparing a polyester resin, a step of adding the monofunctional glycidyl ether compound represented by the above-mentioned general formula (1) and the above-mentioned reaction promoter to prepare a polyester resin composition, a step of melt-extruding the polyester resin composition to form a polyester film, a step of stretching the polyester film and a step of thermally fixing the stretched polyester film.

The timing of adding the monofunctional glycidyl ether compound represented by the above-mentioned general formula (1) and the above-mentioned reaction promoter to the polyester resin is not specifically defined, not overstepping the spirit and the scope of the invention, but preferably, these are added after the polymerization to give the polyester resin has been almost completed. In case where the resin is followed by solid-phase polymerization, it is desirable that the additives are added thereto after solid-phase polymerization. On the other hand, the additives are added before melt-kneading the polyester resin from the viewpoint of uniformly adding them.

One preferred production method for the polyester film of the invention is described below.

### —Esterification Step—

In the invention, there is provided an esterification step of producing a polyester through esterification and polycondensation reaction. The esterification step may comprise (a) esterification and (b) polycondensation of the esterified product produced through the esterification.

### (a) Esterification

PETs may have different properties depending on the catalyst used in producing them, as mentioned below. Preferred are PETs produced through polymerization by the use of one or more selected from a germanium (Ge) catalyst, an antimony (Sb) catalyst, an aluminium (Al) catalyst, and a titanium (Ti) catalyst, and more preferred are those produced with a Ti catalyst.

Any reaction catalyst heretofore known in the art can be used in esterification and/or interesterification. The reaction catalyst includes alkali metal compounds, alkaline earth metal compounds, zinc compounds, lead compounds, manganese compounds, cobalt compounds, aluminium compounds, antinomy compounds, titanium compounds, germanium compounds, phosphorus compounds, etc. In general, in any stage before completion of the polyester production method, it is desirable to add, as a polymerization catalyst, any of an antimony compound, a germanium compound or a titanium compound. In such a method where, for example, a germanium compound is used, it is desirable that the germanium compound powder is added to the reaction system directly as it is.

Further, when the polyester film of the invention is produced, it is also desirable to add a metal complex. Examples of the metal complex include acetylacetonate complexes, carbonyl complexes, cyclopentadienyl complexes, nitrosyl complexes, thiocyanate complexes, acetyl complexes or the like with Ti, Al, Zr or Si.

Preferably, the production method for the polyester film of the invention includes a step of preparing the above-mentioned polyester resin to be subjected to casting film formation, through esterification with a Ti catalyst.

The polyester film containing the polyester resin that has been esterified by the use of a Ti catalyst is preferred as hardly undergoing reduction in weather resistance thereof. Though not adhering to any theory, the reason will be as follows: The reduction in the weather resistance of a weather-resistant polyester film depends on hydrolysis of polyester in some degree. The esterification catalyst may promote hydrolysis that is counter-reaction to esterification, however, the Ti catalyst poorly acts for the counter-reaction, hydrolysis. Consequently, even though the esterification reaction may remain in some degree in the formed polyester film, the polyester resin esterified by the use of such a Ti catalyst could keep relatively high the weather resistance thereof, as compared with any other polyester resin esterified by the use of any other catalyst.

In addition, the Ti catalyst has high reactivity and can lower the temperature for polymerization with it. Accordingly, the catalyst can prevent thermal decomposition of PET to generate COOH during polymerization therewith, and therefore, in the polyester film of the invention, the catalyst is also favorable for controlling AV (the amount of terminal COOH) to fall within the above-mentioned preferred range.

The Ti catalyst includes oxides, hydroxides, alkoxides, carboxylate salts, carbonate salts, oxalate salts, organic chelate titanium complexes, halides, etc. Two or more different types of titanium compounds may be used as the Ti catalyst within the range not detracting from the advantages of the invention.

Examples of the Ti catalyst include titanium alkoxides such as tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, tetrabenzyl titanate, etc.; titanium oxides to be prepared through hydrolysis of titanium alkoxides; titanium-silicon or zirconium composite oxides to be prepared through hydrolysis of mixture of titanium alkoxide and silicon alkoxide or zirconium alkoxide; titanium acetate, titanium oxalate, titanium potassium oxalate, titanium sodium oxalate, potassium titanate, sodium titanate, titanic acid-aluminium hydroxide mixture, titanium chloride, titanium chloride-aluminium chloride mixture, titanium acetylacetonate, organic chelate titanium complexes with an organic acid as the ligand therein, etc.

Of the above-mentioned Ti catalysts, preferred for use herein is at least one organic chelate titanium complex with an organic acid as the ligand therein. The organic acid includes, for example, citric acid, lactic acid, trimellitic acid, malic acid, etc. Above all, preferred are organic chelate complexes with citric acid or a citrate salt as the ligand therein.

In case where a chelate titanium complex with citric acid as the ligand therein is used, few impurities such as fine particles generate and, as compared with any other titanium compound, the catalyst has higher polymerization activity and the color of the obtained polyester resin may be good. Further, even when a citric acid-chelated titanium complex is used but when the complex is added during the stage of esterification, the polymerization activity of the complex is better and the color of the obtained polyester resin may also be better and, in addition, the amount of the terminal carboxyl group in the polyester resin obtained may be small, as compared with the case of adding it after esterification. The reason would be because the titanium catalyst additionally has a catalytic effect for esterification, and therefore, when it is added during esterification, the oligomer acid value may be low after the esterification so that the subsequent polycondensation may be attained more efficiently, and in addition, the complex with citric acid as the ligand therein has higher hydrolysis resistance than that of titanium alkoxide and the like, and therefore during the step of esterification, the complex would not hydrolysis and could therefore effectively function as the catalyst for esterification and polycondensation while maintaining its intrinsic activity as it is.

In addition, in general, it is known that when the amount of the terminal carboxyl group in the polyester is larger, then the hydrolysis resistance of the polyester is poorer; however, according to the addition method of the invention, the amount of the terminal carboxyl group could reduce and the hydrolysis resistance of the polyester could be expected to be higher.

The citric acid-chelated titanium complex is easily available as a commercial product, for example, as VERTEC AC-420 by Johnson Massey.

In this case, the amount of the Ti catalyst is preferably from 1 ppm to 30 ppm, more preferably from 2 ppm to 25 ppm, even more preferably from 3 ppm to 20 ppm. Further adding a phosphorus compound is preferred as more noticeably augmenting the effect.

When the amount of the Ti compound is at least 1 ppm in terms of the Ti element therein, the polymerization speed could be high and the amount of the terminal carboxyl group in the obtained polyester could fall within the preferred range. When the amount of the Ti compound is at most 30 ppm in terms of the Ti element therein, it is possible to control AV (terminal COOH amount) to fall within the above-mentioned range, and the color of the obtained polyester resin may be good.

For production of such Ti-assisted polyesters using the Ti compound of the type, for example, the methods described in JP-B 8-30119, Japanese Patent 2543624, 3335683, 3717380, 3897756, 3962226, 3979866, 3996871, 4000867, 4053837, 4127119, 4134710, 4159154, 4269704, 4313538, JP-A 2005-340616, 2005-239940, 2004-319444, 2007-204538, Japanese Patent 3436268, 3780137 and others are applicable.

In the invention, preferably, the production process includes at least an esterification step, in which an aromatic dicarboxylic acid and an aliphatic diol are polymerized in the presence of a catalyst containing a titanium compound, in which at least one titanium compound is an organic chelate titanium complex with an organic acid as the ligand therein, and in which the organic chelate titanium complex, a magnesium compound and a pentavalent phosphate ester not having an aromatic ring as the substituent are added to the system in that order. For this case, also preferred is an embodiment which includes, in addition to the esterification step, a polycondensation step of forming a polycondensate through polycondensation of the esterified reaction product produced in the esterification step, thereby producing a polyester film according to the polyester resin production step of this embodiment. The polycondensation step is described hereinunder.

In this case, during the esterification step, a magnesium compound may be added to the system where an organic chelate titanium compounds exists as the titanium compound, and then a specific pentavalent phosphorus compound may be added in that order, whereby the reaction activity of the titanium catalyst can be kept high and the electrostatic property of magnesium can be imparted to the system and, in addition, the decomposition reaction can be effectively inhibited during polycondensation; and as a result, a polyester resin with little discoloration can be obtained and the obtained polyester resin can have high electrostatic characteristics and can be prevented from yellowing when exposed to high-temperature environments.

Accordingly, there can be provided a polyester resin which discolors little in polymerization and also in subsequent casting film formation, which, as compared with the polyester resin produced by the use of a conventional antimony (Sb) catalyst, yellows little, and which, as compared with the polyester resin produced by the use of a germanium catalyst having relatively high transparency, has color and transparency comparable with those of the polyester resin produced by the use of such a germanium catalyst, and additionally has excellent heat resistance. In addition, not using a cobalt compound or any other coloration-regulating agent such as a dye or the like, a polyester resin that yellows little can be obtained.

The polyester resin is applicable to use that requires high transparency (for example, for optical films, industrial lithography materials, etc.) and does not require an expensive germanium catalyst, and therefore contributes toward significant cost reduction. In addition, the polyester resin is prevented from contamination with catalyst-derived impurities, which often occurs in a Sb catalyst-assisted system, and accordingly, the polyester resin is free from troubles in the process of film formation and from problems of poor quality of film products, and therefore can contribute toward cost reduction through increase in the production yield.

In the above, in case where the aromatic dicarboxylic acid and the aliphatic diol are mixed with a catalyst that contains a titanium compound of an organic chelate titanium complex prior to adding a magnesium compound and a phosphorus compound thereto, the organic chelate titanium complex and others have high catalytic activity for esterification, and therefore facilitate esterification. In this case, a titanium compound may be added to a mixture of a dicarboxylic acid component and a diol component. Alternatively, after a dicarboxylic acid component (or a diol component) is mixed with a titanium compound, the resulting mixture may be added to a diol component (or a dicarboxylic acid component). A dicarboxylic acid component, a diol component and a titanium compound may be mixed all at a time. The mode of mixing them is not specifically defined, for which is employable any known method.

In esterification, preferably, a titanium compound of an organic chelate titanium complex, and as additives, a magnesium compound and a pentavalent phosphorus compound are added to the system in that order. In this case, in the presence of an organic chelate titanium complex, the esterification is promoted and thereafter a magnesium compound is added to the system prior to adding a phosphorus compound.

As the pentavalent phosphorus compound, herein usable is at least one pentavalent phosphate ester not having an aromatic ring as the substituent. The pentavalent phosphate ester includes, for example, trimethyl phosphate, triethyl phosphate, tri-n-butyl phosphate, trioctyl phosphate, tris(triethylene glycol) phosphate, methylphosphoric acid, ethylphosphoric acid, isopropylphosphoric acid, butylphosphoric acid, monobutyl phosphate, dibutyl phosphate, dioctyl phosphate, triethylene glycol phosphoric acid, etc.

Of pentavalent phosphate esters, preferred are phosphate esters having, as the substituent, a lower alkyl group with at least 2 carbon atoms [(OR)₃—P═O, where R represents an alkyl group having 1 or 2 carbon atoms], and concretely, trimethyl phosphate and triethyl phosphate are more preferred.

In particular, in case where a chelate titanium complex with citric acid or its salt as the ligand thereof is used as the titanium compound serving as a catalyst, pentavalent phosphate esters are better than trivalent phosphate esters in point of the polymerization activity thereof and the color of the polyester to be obtained. In particular, in an embodiment where a pentavalent phosphate ester having at most 2 carbon atoms is added, the balance among the polymerization activity of the catalyst, and the color and the heat resistance of the obtained polyester can be especially bettered.

Preferably, the amount of the phosphorus compound to be added is so controlled that the amount of the P element could be from 50 ppm to 90 ppm. The amount of the phosphorus compound is more preferably so controlled as to fall within a range of from 60 ppm to 80 ppm, even more preferably from 65 ppm to 75 ppm.

The esterification can be attained in a multistage apparatus in which at least two reactors are connected in series, under the condition under which ethylene glycol could be kept under reflux, while water or alcohol formed through the reaction are removed out of the reaction system.

A slurry of a dicarboxylic acid and a diol may be prepared and this may be continuously introduced into the esterification system.

The esterification may be attained in one stage or in multiple stages.

### (b) Polycondensation

The esterified product produced through the esterification is polycondensed to give a polycondensation product. The polycondensation may be attained in one stage or in multiple stages.

The esterified product such as oligomer and the like produced in the esterification is subsequently polycondensed.

Preferably, the polycondensation is attained by introducing the esterified product into a multistage polycondensation reaction system.

For example, a preferred embodiment of the polycondensation condition in a three-stage reactor system is as follows: In the first reactor, the reaction temperature is from 255 to 280° C., preferably from 265 to 275° C., and the pressure is from 13.3×10⁻³ to 1.3×10⁻³ MPa (100 to 10 Torr), more preferably from 6.67×10⁻³ to 2.67×10⁻³ MPa (50 to 20 Torr); in the second reactor, the reaction temperature is from 265 to 285° C., preferably from 270 to 280° C., and the pressure is from 2.67×10⁻³ to 1.33×10⁻⁴ MPa (20 to 1 Torr), more preferably from 1.33×10⁻³ to 4.0×10⁻⁴ MPa (10 to 3 Torr); in the third reactor in the final reactor system, the reaction temperature is from 270 to 290° C., preferably from 275 to 285° C., and the pressure is from 1.33×10⁻³ to 1.33×10⁻⁵ MPa (10 to 0.1 Torr), more preferably from 6.67×10⁻⁴ to 6.67×10⁻⁵ MPa (5 to 0.5 Torr).

Elements of Ti, Mg and P may be determined through high-resolution inductively-coupled plasma mass spectrometry (HR-ICP-MS; SII Nanotechnology's AttoM) in which the elements in PET are quantified. From the found data, the content of each element [ppm] may be derived through computation.

### —Solid-Phase Polymerization Step—

The production method for the polyester film of the invention preferably includes a step of heat-treating a polyester resin at from 190° C. to 230° C. for 10 to 80 hours to prepare the polyester resin for casting film formation, from the viewpoint of controlling the above-mentioned AV to fall within the preferred range.

Specifically, it is desirable that the production method for the polyester film of the invention further includes a solid-phase polymerization step of processing the polyester film to be used for solid-phase polymerization prior to melting the polyester. For the solid-phase polymerization, it is desirable that the polyester produced according to the above-mentioned esterification or a commercially-available polyester is pelletized into small pellets and these are processed for solid-phase polymerization.

The preferred solid-phase polymerization temperature is from 190 to 230° C., more preferably from 200° C. to 220° C., even more preferably from 205° C. to 215° C.

The preferred solid-phase polymerization time is from 10 hours to 80 hours, more preferably from 15 hours to 50 hours, even more preferably from 20 hours to 30 hours.

The heat treatment is attained preferably in a low-oxygen atmosphere, for example, preferably in a nitrogen atmosphere or in vacuum. Further, a polyalcohol (ethylene glycol or the like) may be added to the system in an amount of from 1 ppm to 1%.

The solid-phase polymerization may be attained in a batch mode (in which resin is put into a container and stirred under heat for a predetermined period of time), or in a continuous mode (in which resin is put into a heated cylinder, and led to pass through it sequentially while kept heated under reflux therein for a predetermined period of time).

### (Formation of Polyester Film)

### (1) Melt Extrusion for Film Formation

Preferably, in the production method of the invention, the polyester after the solid-phase polymerization step is melt-kneaded and extruded out through a nozzle (extrusion die) to form a polyester film.

Preferably, the polyester obtained in the solid-phase polymerization step is dried. For example, the polyester is dried so as to have a residual water content of at most 100 ppm.

In the production method of the invention, the polyester film may be melt-kneaded by the use of an extruder. The melting temperature (this may be referred to also as kneading temperature) varies depending on the type of the polyester resin. For example, PET is melted at 250° C. to 320° C., more preferably at 260° C. to 310° C., particularly preferably at 270° C. to 300° C., more particularly preferably at 270 to 285° C.

The extruder may be a single-screw one or a multi-screw one. From the viewpoint of preventing formation of terminal COOH through thermal decomposition, more preferably, the extruder is purged with nitrogen.

Preferably, the molten polyester resin (resin melt) is extruded out through the extrusion die via a gear pump, a filter and the like. In this, the resin may be extruded as a single layer or as a multilayer structure.

In case where the molten resin (melt) is discharged out (for example, extruded out through a die), preferably, the shear rate in discharging is controlled to fall within a preferred range. Preferably, the shear rate in extrusion is from 1 s⁻¹ to 300 s⁻¹, more preferably from 10 s to 200 s, even more preferably from 30 s⁻¹ to 150 s⁻¹. Accordingly, for example, when the resin melt is extruded out through a die, there occurs a phenomenon of die swelling (that the melt swells in the thickness direction). Specifically, a stress is given to the melt in the thickness direction (in the normal direction of the film), and therefore the molecular movement in the thickness direction of the melt is thereby promoted and COOH group and OH group can be made to exist in the melt. When the shear rate is at least 1 s⁻¹, then COOH group and OH group can be fully stepped in the inside of the melt; and when at most 300 s⁻¹, then COOH group and OH group can be made to exist in the surface of the film.

After the molten resin (melt) is discharged out (for example, extruded out through a die), preferably, the air gap between the melt and the casting roll is so controlled that the relative humidity therein is from 5 to 60%, more preferably from 10 to 55%, even more preferably from 15 to 50%. By controlling the relative humidity in the air gap to fall within the above range, the hydrophobicity of air can be controlled and the degree of COOH group and OH group to step in the inside of the film from the film surface can be controlled.

Preferably, the extruded melt is cooled on a support and solidified to give a film thereon.

Not specifically defined, the support may be any chill roll generally used in ordinary casting film formation.

The temperature of the chill roll itself is preferably from 10° C. to 80° C., more preferably from 15° C. to 75° C., even more preferably from 20° C. to 60° C. Further, from the viewpoint of increasing the adhesiveness between the molten resin (melt) and the chill roll to thereby enhance the cooling efficiency, it is desirable that static electricity is previously applied to the chill roll before the melt is brought into contact with it.

The thickness of the solidified (but unstretched) molten resin (melt) that has been discharged out like a strip falls within a range of from 2600 μm to 6000 μm; and after stretched, the solidified melt gives a polyester film having a thickness of from 260 μm to 400 μm. The thickness of the solidified melt is preferably within a range of from 3100 μm to 6000 μm, more preferably from 3300 μm to 5000 μm, further preferably from 3500 μm to 4500 μm. When the thickness of the solidified but unstretched film is at most 6000 μm, the film hardly wrinkles during melt extrusion and is prevented from being uneven. Preferably, the thickness of the solidified but unstretched film is at least 2600 μm from the viewpoint of preventing adhesion unevenness of the film to the chill roll (cooling roll for solidification) to occur owing to poor toughness of the melt, and from the viewpoint of reducing film unevenness.

### (Stretching Step)

Preferably, the production method for the polyester film of the invention includes a step of stretching the film formed through extrusion (unstretched film) after the film formation step. The mode of stretching the film is not specifically defined. Preferably, the polyester film of the invention is produced in a mode of biaxial stretching. The local temperature unevenness and wind speed unevenness in thermal fixation to be mentioned below are not effected by the stretching unevenness in the stretching step.

In biaxial stretching, the order of longitudinal stretching and lateral stretching is not specifically defined, and any of these may be carried out first. Preferably, longitudinal stretching is carried out first.

Preferably, the stretching includes longitudinal stretching and lateral stretching for a total of at most three times each, more preferably longitudinal stretching and lateral stretching for a total of at most two times, and even more preferably longitudinal stretching and lateral stretching each once.

Any of longitudinal stretching and lateral stretching may be carried out first, but preferably, longitudinal stretching is carried out first. In this case, preferably, the draw ratio of latter stretching is higher than that of former stretching.

In the production method for the polyester film of the invention, preferably, the draw ratio in longitudinal stretching is larger than that in lateral stretching. Preferably, draw ratio in longitudinal stretching/draw ratio in lateral stretching is from 1.03 to 1.3, more preferably from 1.05 to 1.25, even more preferably from 1.06 to 1.2. In general, the film is first longitudinally stretched and then laterally stretched, and concretely, the polyester resin first oriented through longitudinal stretching is thereafter re-oriented through lateral stretching. In the method for producing the polyester film of the invention, the draw ratio in lateral stretching is kept higher, whereby the degree of longitudinally-oriented molecules can be made equal to the degree of the laterally-oriented molecules in the stretched film. As a result, the longitudinally-oriented molecules can be readily entangled with the laterally-oriented molecules, and the entangled points can be crosslinked points. Owing to the crosslinked points, the mobility of the molecules is lowered thereby facilitating the formation of a poorly-mobile component in the film.

The ratio of the draw ratio in longitudinal stretching to the draw ratio in lateral stretching (longitudinal draw ratio/lateral draw ratio) is preferably 1±0.2, more preferably 1±0.17, even more preferably 1±0.15.

In the method for producing the polyester film of the invention, preferably, the areal draw ratio in stretching is from 11 times to 15 times, more preferably from 11.5 times to 14.5 times, even more preferably from 12 times to 14 times. In this, the areal draw ratio in stretching means the product of the draw ratios in the entire stretching step, and for example, when a film is stretched by A times longitudinally and then by B times laterally, the areal draw ratio is A×B times. When the areal draw ratio is not lower than the lower limit of the above range, the molecular orientation could be sufficient, and crystals may readily form in subsequent thermal fixation. As a result, a poorly-mobile component of which the mobility between the crystals therein is restrained could be readily formed. On the other hand, when the areal draw ratio is not higher than the upper limit of the above range, then the molecules are not too much strained and the poorly-mobile molecules existing between the crystals are hardly pulled out of the crystals, therefore providing an advantage that the amount of the poorly-mobile component is prevented from reducing.

Preferably, in the production method for the polyester film of the invention, the draw ratio in lateral stretching/draw ratio in longitudinal stretching is from 1.03 to 1.3 times and the areal draw ratio is from 11 to 15 times.

Also preferably, the draw ratio in stretching in a different direction is within a range of from 3 times to 5 times both in the film longitudinal direction (film traveling direction) and in the film crosswise direction (direction perpendicular to film traveling direction).

In the production method for the polyester film of the invention, preferably, the stretching temperature is from 80° C. to 160° C., more preferably from 85° C. to 155° C., even more preferably from 90° C. to 150° C. When the temperature is not higher than the upper limit of the preferred range, then the molecular orientation is not too much lowered by stretching, and as a result, crystals can be readily formed in thermal fixation, or that is, a poorly-mobile component in which the crystals are fixed to lower the mobility thereof is readily formed. On the other hand, when the temperature is not lower than the lower limit of the preferred range, then the polyester molecules are hardly cut during stretching and can secure the strength (molecular weight) necessary for bridging the crystals in the film. As a result, a poorly-mobile component fixed between crystals is readily formed in the film.

In the production method for the polyester film of the invention, when the film is biaxially stretched, it is desirable that the stretching temperature in the latter stretching is higher by from 10° C. to 80° C. than the stretching temperature in the former stretching, more preferably by from 15° C. to 70° C., even more preferably by from 20° c. to 60° C. The latter-stage stretching is for breaking the orientation of the molecules that have been once oriented in the former-stage stretching and re-arranging them, and therefore requires larger energy, and consequently, the temperature in the latter-stage stretching is preferably higher by the above-mentioned range than the temperature in the former-stage stretching. In that manner, the molecules could be readily entangled together more efficiently to form nodular points, and the mobility of the molecules around the nodular points lowers to readily form a poorly-mobile component in the film.

One concrete stretching method is described. For example, it is desirable that an unstretched polyester film is introduced into rolls heated at a temperature of from 70° C. to 140° C., then stretched in the longitudinal direction (lengthwise direction, or that is the film traveling direction) by 3 times to 5 times, and thereafter cooled with rolls at a temperature of from 20° C. to 50° C. Subsequently, it is desirable that, while both sides thereof are clipped, the film is led to a tenter and stretched therein in the direction (lateral direction) perpendicular to the longitudinal direction of the film in an atmosphere heated at a temperature of from 80° C. to 150° C., at a draw ratio of from 3 times to 5 times.

The biaxial stretching method may be any of a successive biaxial stretching method where stretching in the longitudinal direction and stretching in the lateral direction are attained separately, or a simultaneous biaxial stretching method where stretching in the longitudinal direction and stretching in the lateral direction are attained simultaneously, as mentioned above.

In this case, preferably, the thickness of the stretched film is so controlled as to fall within the preferred range of the thickness of the polyester film of the invention.

### (Thermal Fixation)

The method for producing the polyester film of the invention may include a step of thermally fixing the stretched polyester film.

The thermal fixation temperature (hereinafter this may be referred to as Tk) in the thermal fixation zone is preferably from 180° C. to 230° C., more preferably from 185° C. to 225° C., even more preferably from 195° C. to 220° C., still more preferably from 200 to 215° C. When the temperature range is as above, the amount of the crystals to be formed through the previous thermal fixation can be controlled to be within the preferred range. The thermal fixation time is preferably a few seconds, and may be, for example, from 1 to 3 seconds.

If desired, the film may be or may not be processed for relation treatment in the lateral direction or in the longitudinal direction, not contradictory to the spirit and the scope of the invention.

In the method for producing the polyester film of the invention, the relaxation treatment is preferably attained after thermal fixation. In case where the film is processed for relaxation treatment after thermal fixation, the degree of relaxation is preferably from 1 to 30%, more preferably from 2 to 25%, even more preferably from 2 to 20%.

Preferably, the relaxation treatment is attained in film crosswise direction (direction perpendicular to the film traveling direction, or that is, the lateral direction of the film).

### (Formation and Drying of Coating Layer)

Preferably, the production method for the polyester film of the invention includes a step of forming a coating layer on the polyester film by coating thereon, followed by drying it in a drying zone to thereby form the coating layer on the film, after the thermal fixation step, in which, preferably, the heat treatment step is carried out in the drying zone from the viewpoint that the surface condition of the film can be prevented from worsening.

### <Back Sheet for Solar Cells>

The back sheet for solar cells of the invention contains the polyester film of the invention.

The back sheet for solar cells of the invention comprises the polyester film of the invention mentioned above, and may comprise at least one functional layer such as an easy adhesion layer for facilitating adhesion of the sheet to an adherend, a UV absorbent layer, a light-reflecting white layer, etc. As containing the polyester film mentioned above, the back sheet exhibit stable durability in long-term use.

The back sheet for solar cells of the invention may be produced, for example, by providing a functional layer mentioned below on a monoaxially stretched and/or biaxially stretched polyester film. For providing the functional layer, employable is any known coating technique of a roll coating method, a knife edge coating method, a gravure coating method, a curtain coating method or the like.

Before coating with the layer, the film may be surface-treated (flame treatment, corona treatment, plasma treatment, UV treatment or the like). Also preferably, the coating layer may be adhered to the film by using an adhesive.

### —Easy Adhesion Layer—

In case where the polyester film of the invention is used for constructing a solar cell module, preferably, the film has an easy adhesion layer on the side of the sealant on the cell-side substrate of a solar cell element sealed up with a sealant. Thus providing an easy adhesion layer capable of exhibiting adhesiveness to an adherend containing a sealant (especially ethylene/vinyl acetate copolymer) (for example, the surface of the sealant on the cell-side substrate of a solar cell element sealed up with a sealant) enhances the adhesiveness between the back sheet and the sealant. Concretely, it is desirable that the easy adhesion layer has an adhesion power to EVA (ethylene/vinyl acetate copolymer) serving as a sealant of at least 10 N/cm, more preferably at least 20 N/cm.

Further, the easy adhesion layer must prevent the back sheet from peeling away during use of solar cell modules, and for this, it is desirable that the easy adhesion layer has high wet heat resistance.

### (1) Binder

The easy adhesion layer in the invention may contain at least one binder.

As the binder, for example, usable are polyesters, polyurethanes, acrylic resins, polyolefins, etc. Above all, from the viewpoint of the durability thereof, preferred are acrylic resins and polyolefins. As the acrylic resin, also preferred is a composite resin of acryl and silicone. Preferred examples of the binder are mentioned below.

Examples of polyolefins include Chemipearl S-120, S-75N (both by Mitsui Chemical). Examples of acrylic resins include Jurymer ET-410, SEK-301 (both by Nihon Junyaku). Examples of composite resin of acryl and silicone include Ceranate WSA1060, WSA1070 (both by DIC), and H7620, H7630, H7650 (all by Asahi Kasei Chemicals).

Preferably, the amount of the binder is from 0.05 to 5 g/m², more preferably from 0.08 to 3 g/m². When the amount of the binder is at least 0.05 g/m², then the layer can exhibit good adhesion power, and when at most 5 g/m², then the layer can secure good surface condition.

### (2) Fine Particles

The easy adhesion layer in the invention may contain at least one type of fine particles. Preferably, the adhesion layer contains fine particles in an amount of at least 5% by mass relative to the mass of the entire layer.

As the fine particles, preferred are inorganic fine particles of silica, calcium carbonate, magnesium oxide, magnesium carbonate, tin oxide, etc. Of those, more preferred are fine particles of tin oxide or silica from the viewpoint that, when the layer containing them is exposed to wet heat atmosphere, the reduction in the adhesiveness of the layer is small.

Preferably, the particle size of the fine particles is from 10 to 700 nm or so, more preferably from 20 to 300 nm or so. Using fine particles of which the particle size falls within the range secures good adhesiveness of the layer. The shape of the fine particles is not specifically defined. For example, the fine particles may be spherical, amorphous, acicular or the like ones.

The amount of the fine particles to be in the easy adhesion layer is preferably from 5 to 400% by mass of the binder in the easy adhesion layer, more preferably from 50 to 300% by mass. When the amount of the fine particles is at least 5% by mass, then the easy adhesion layer can still maintain good adhesiveness even when exposed to wet heat environment; and when at most 1000% by mass, then the surface condition of the layer could be better.

### (3) Crosslinking Agent

The easy adhesion layer in the invention may contain at least one crosslinking agent.

Examples of the crosslinking agent include epoxy-type, isocyanate-type, melamine-type, carbodiimide-type, or oxazoline-type crosslinking agents. From the viewpoint of securing the adhesiveness after aging in wet heat, oxazoline-type crosslinking agents are preferred of the above.

Specific examples of oxazoline-type crosslinking agents include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis(2-oxazoline), 2,2′-methylenebis(2-oxazoline, 2,2′-ethylenebis(2-oxazoline), 2,2′-trimethylenebis(2-oxazoline), 2,2′-tetramethylenebis(2-oxazoline, 2,2′-hexamethylenebis(2-oxazoline), 2,2′-octamethylenebis(2-oxazoline), 2,2′-ethylenebis(4,4′-dimethyl-2-oxazoline), 2,2′-p-phenylenebis(2-oxazoline), 2,2′-m-phenylenebis(2-oxazoline), 2,2′-m-phenylenebis(4,4′-dimethyl-2-oxazoline), bis(2-oxazolinylcyclohexane) sulfide, bis(2-oxazolinylnorbornane) sulfide, etc. Further, co(polymers) of those compounds are also preferably used here.

In addition, compounds having an oxazoline group such as Epocross K2010E, K2020E, K2030E, WS500, WS700 (all by Nippon Shokubai) are usable here.

The amount of the crosslinking agent to be in the easy adhesion layer is preferably from 5 to 50% by mass of the binder in the easy adhesion layer, more preferably from 20 to 40% by mass. When the amount of the crosslinking agent is at least 5% by mass, then the agent can exhibit good crosslinking effect, therefore preventing the intensity reduction or adhesion failure of the reflection layer adjacent to the easy adhesion layer; and when at most 50% by mass, the pot life of the coating liquid for the layer can be kept long.

### (4) Additive

If desired, any known mat agent such as polystyrene, polymethyl methacrylate, silica or the like and any known surfactant such as an anionic or nonionic surfactant or the like may be added to the easy adhesion layer in the invention.

### (5) Method for Forming Easy Adhesion Layer

For forming the easy adhesion layer in the polyester film of the invention, there are mentioned a method of sticking an easy-adhesive polymer sheet to a polyester film, and a method of forming the easy adhesion layer by coating. The coating method is preferred from the viewpoint that the method is simple and can form a highly-uniform thin coating film. For the coating method, for example, usable is any known gravure coater, bar coater or the like. The solvent for the coating liquid may be water, or may also be an organic solvent such as toluene, methyl ethyl ketone or the like. One alone or two or more different types of such solvents may be used either singly or as combined.

In case where the easy adhesion layer is formed by coating, preferably, the coating layer is dried and heat-treated in the drying zone after heat treatment, as described in the section of the production method for the polyester film of the invention. The same applies to the case where a colorant layer and other layers are formed by coating.

### (6) Physical Properties

The thickness of the easy adhesion layer in the invention is not specifically defined. In general, the thickness is preferably from 0.05 to 8 μm, more preferably from 0.1 to 5 μm. When the thickness of the easy adhesion layer is at least 0.05 μm, then the layer can readily exhibit the necessary easy adhesiveness; and when at most 8 μm, the layer can keep good surface condition.

Preferably, the easy adhesion layer in the invention is transparent from the viewpoint that, when a colorant layer (especially a reflection layer) is arranged between the easy adhesion layer and the polyester film, the easy adhesion layer does not detract from the effect of the colorant layer.

### —Colorant Layer, Reflection Layer—

A colorant layer may be arranged in the polyester film of the invention. The colorant layer is arranged in the polyester film while kept in contact with the surface of the film or while spaced from it via any other layer arranged therebetween, and the layer may contain a pigment and a binder.

The first function of the colorant layer is to reflect the light part of the incident light, which has not been used for power generation in a solar cell element but has reached the back sheet, so as to return back it to the solar cell element to thereby increase the power generation efficiency of the solar cell module. The second function is to enhance the decorative design of the outward appearance of a solar cell module when seen from its front side. In general, when a solar cell module is seen from its front side, the back sheet is seen around the solar cell element therein, but by providing a colorant layer on the back sheet in the module, the decorative design of the module can be bettered.

### (1) Pigment

The colorant layer in the invention may contain at least one pigment. Preferably, the amount of the pigment to be in the layer is from 2.5 to 8.5 g/m². More preferably, the pigment amount is from 4.5 to 7.5 g/m². When the pigment amount is at least 2.5 g/m², then the layer readily secures the necessary coloration and can control the light reflectivity and can further better the decorative design of the module. When the pigment content is at most 8.5 g/m², then the surface condition of the colorant layer can be kept better.

The pigment includes, for example, inorganic pigments such as titanium oxide, barium sulfate, silicon oxide, aluminium oxide, magnesium oxide, calcium carbonate, kaolin, talc, ultramarine, Prussian blue, carbon black, etc.; organic pigments such as phthalocyanine blue, phthalocyanine green, etc. Of those pigments, preferred are white pigments from the viewpoint that the colorant layer could act as a reflection layer that reflects the incident light thereto. For example, preferred are titanium oxide, barium sulfate, silicon oxide, aluminium oxide, magnesium oxide, calcium carbonate, kaolin, talc, etc.

The mean particle size of the pigment is preferably from 0.03 to 0.8 μm, more preferably from 0.15 to 0.5 μm or so. When the mean particle size falls within the range, then the light reflection efficiency of the particles may lower.

In case where the colorant layer acts as a reflection layer that reflects the incoming sunlight, the amount of the pigment to be in the reflection layer may vary depending on the type and the mean particle size of the pigment to be used and therefore could not be indiscriminately defined. However, the amount is preferably from 1.5 to 15 g/m², more preferably from 3 to 10 g/m² or so. When the amount is at least 1.5 g/m², then the layer can readily secure the necessary reflectivity; and when at most 15 g/m², then the strength of the reflection layer can be kept further higher.

### (2) Binder

The colorant layer in the invention may contain at least one binder. The amount of the binder, if any, in the layer is preferably from 15 to 200% by mass of the pigment therein, more preferably from 17 to 100% by mass. When the amount of the binder is at least 15% by mass, then the strength of the colorant layer can be kept better; and when at most 200% by mass, the reflectivity and the decorative design of the layer may worsen.

The binder favorable for the colorant layer includes, for example, polyesters, polyurethanes, acrylic resins, polyolefins, etc. Above all, from the viewpoint of the durability thereof, acrylic resins and polyolefins are preferred for the binder. As the acrylic resin, also preferred is a composite resin of acryl and silicone. Preferred examples of the binder are mentioned below.

Examples of polyolefins include Chemipearl S-120, S-75N (both by Mitsui Chemical). Examples of acrylic resins include Jurymer ET-410, SEK-301 (both by Nihon Junyaku). Examples of composite resin of acryl and silicone include Ceranate WSA1060, WSA1070 (both by DIC), and H7620, H7630, H7650 (all by Asahi Kasei Chemicals).

### (3) Additive

The colorant layer in the invention may optionally contain a crosslinking agent, a surfactant, a filler and others, in addition to the binder and the pigment.

The crosslinking agent includes epoxy-type, isocyanate-type, melamine-type, carbodiimide-type, oxazoline-type and the like crosslinking agents. The amount of the crosslinking agent in the colorant layer is preferably from 5 to 50% by mass of the binder therein, more preferably from 10 to 40% by mass. When the amount of the crosslinking agent is at least 5% by mass, then the agent can exhibit good crosslinking effect and the strength and the adhesiveness of the colorant layer can be thereby kept high; and when at most 50% by mass, the pot life of the coating liquid for the layer can be kept long.

As the surfactant, any known surfactant such as anionic or nonionic surfactant can be used. The amount of the surfactant to be added is preferably from 0.1 to 15 mg/m², more preferably from 0.5 to 5 mg/m². When the amount of the surfactant is at least 0.1 mg/m², then the coating failure can be effectively prevented; and when at most 15 mg/m², the adhesiveness of the layer is excellent.

Apart from the above-mentioned pigment, any other filler such as silica or the like may be added to the colorant layer. The amount of the filler to be added is preferably at most 20% by mass of the binder in the colorant layer, more preferably at most 15% by mass. When containing such a filler, the strength of the colorant layer can be enhanced. When the amount of the filler is at most 20% by mass, then the ratio of the pigment in the layer can be kept good and the layer secures good light reflection (reflectivity) and good decorative design.

### (4) Method for Forming Colorant Layer

For forming the colorant layer, herein employable are a method of sticking a pigment-containing polymer sheet to the polyester film, a method of co-extruding the colorant layer in producing the polyester film, a coating method, etc. Of those, the coating method is preferred as simple and capable of forming a highly-uniform and thin coating layer. For the coating method, for example, usable is any known gravure coater, bar coater or the like. The solvent for the coating liquid may be water, or may also be an organic solvent such as toluene, methyl ethyl ketone or the like. However, from the viewpoint of environmental load, the solvent is preferably water.

One alone or two or more different types of such solvents may be used either singly or as combined.

### (5) Physical Properties

Preferably, the colorant layer is formed as a white layer (light reflection layer) containing a white pigment. The light reflectivity at 550 nm of the white layer is preferably at least 75%. When the reflectivity is at least 75%, then the layer is effective for returning the sunlight that has passed through the solar cell element and has not used for power generation back to the cell, therefore effectively increasing the power generation efficiency of the cell.

Preferably, the thickness of the white layer (light reflection layer) is from 1 to 20 μm, more preferably from 1 to 10 μm, even more preferably from 1.5 to 10 μm or so. When the thickness is at least 1 μm, then the layer can readily secure the necessary decorative design and reflectivity; and when at most 20 μm, the surface condition of the layer may worsen.

### —Undercoat Layer—

An undercoat layer may be provided in the polyester film of the invention. For example, in case where a colorant layer is provided in the polyester film, the undercoat layer may be provided between the colorant layer and the polyester film. The undercoat layer may comprise a binder, a crosslinking agent, a surfactant, etc.

The binder to be in the undercoat layer includes polyesters, polyurethanes, acrylic resins, polyolefins, etc. In addition to the binder thereto, a crosslinking agent such as an epoxy-type, isocyanate-type, melamine-type, carbodiimide-type, oxazoline-type or the like crosslinking agent, a surfactant such as an anionic, nonionic or the like surfactant, and a filler such as silica or the like may be added to the undercoat layer.

The method for forming the undercoat layer and the solvent for the coating liquid for the layer are not specifically defined.

For the coating method, for example, usable is a gravure coater, a bar coater or the like. The solvent may be water, or may also be an organic solvent such as toluene, methyl ethyl ketone or the like. One alone or two or more different types of such solvents may be used either singly or as combined.

The coating may be on the biaxially-stretched polyester film or may also be on a monoaxially-stretched polyester film. In this case, after coated, the film may be further stretched in the direction different from the previous stretching direction. In addition, after the stretched polyester film is thus coated, the film may be stretched in two directions.

Preferably, the thickness of the undercoat layer is from 0.05 μm to 2 μm, more preferably from 0.1 μm to 1.5 μm or so. When the thickness is at least 0.05 μm, the layer can readily secure the necessary adhesiveness; and when at most 2 μm, then the surface condition of the layer can be kept good.

### —Barrier Layer—

An also preferred embodiment of the polyester film of the invention has a barrier layer (hereinafter this may be referred to as an inorganic layer). The inorganic layer, when provided, can impart to the film the function of moisture-proofness and gas barrier property capable of preventing invasion of water and gas into the polyester. The inorganic layer may be provided on any of the surface and the back of the polyester film, but from the viewpoint of waterproofness and moisture-proofness, the layer is provided preferably on the side of the polyester film opposite to the side thereof that faces the cell-side support (or that is, the side of the film on which the colorant layer and the easy adhesion layer are provided).

The water vapor penetration rate (moisture permeability) through the inorganic layer is preferably from 10° g/m²·day to 10⁻⁶ g/m²·day, more preferably from 10⁻¹ g/m²·day to 10⁻⁵ g/m²·day, even more preferably from 10⁻² g/m²·day to 10⁻⁴ g/m²·day.

For forming the inorganic layer having the moisture permeability as above, preferred is the following dry method.

The method for forming a gas-barrier inorganic layer (hereinafter this may be referred to as a gas barrier layer) according to a dry method includes various physical vapor deposition methods (PVD methods) of, for example, a vacuum evaporation method of resistance heating vapor deposition, electron beam vapor deposition, induction heating vapor deposition or those assisted with plasma or ion beams, etc.; a sputtering method such as a reactive sputtering method, an ion beam sputtering method, an ECR (electron cyclotron resonance) sputtering method, etc.; an ion plating method, etc.; as well as chemical vapor deposition methods (CVD methods) using heat, light, plasma, etc. Above all, preferred is a vacuum vapor deposition method of forming a film through vapor deposition in vacuum.

In case where the material to form the gas barrier layer comprises, as the main constitutive ingredient thereof, an inorganic oxide, an inorganic nitride, an inorganic oxynitride, an inorganic halide, an inorganic sulfide or the like, it may be possible to directly evaporate a material having the same composition as that of the gas barrier layer to be formed to thereby deposit it on a substrate; however, according to the method, the composition may vary during evaporation and, as a result, the formed film could not have uniform characteristics. Accordingly, there are mentioned 1) a method where a material having the same composition as that of the barrier layer to be formed is used as the evaporation source, and in case where an inorganic oxide is formed, an oxygen gas is used, where an inorganic nitride is formed, a nitrogen gas is used, where an inorganic oxynitride is formed, a mixed gas of oxygen gas and nitrogen gas is used, where an inorganic halide is formed, a halogen gas is used, and where an inorganic sulfide is formed, a sulfur gas is used, and while the respective gas is subsidiarily introduced into the system, the evaporation source is evaporated; 2) a method where an inorganic substance is used as the evaporation source, and while it is evaporated, an oxygen gas is introduced into the system when an inorganic oxide is formed, or a nitrogen gas is thereinto when an inorganic nitride is formed, or a mixed gas of oxygen gas and nitrogen gas is thereinto when an inorganic oxynitride is formed, or a halogen gas is thereinto when an inorganic halide is formed, or a sulfur gas is thereinto when an inorganic sulfide is formed, and the inorganic substance is reacted with the gas thus introduced into the system to thereby deposit the intended inorganic material on the surface of a substrate; 3) a method where an inorganic substance is used as the evaporation source and this is evaporated to form a layer of the inorganic substance, and in case where an inorganic oxide is formed, the system is kept in an oxygen gas atmosphere, where an inorganic nitride is formed, the system is kept in a nitrogen gas atmosphere, where an inorganic oxynitride is formed, the system is kept in a mixed gas atmosphere of oxygen gas and nitrogen gas, where an inorganic halide is formed, the system is kept in a halogen gas atmosphere, and where an inorganic sulfide is formed, the system is kept in a sulfur gas atmosphere, thereby reacting the inorganic layer with the introduced gas.

Of those, preferred is the method 2) or 3) from the viewpoint that the evaporation source can be readily evaporated. More preferred is the method 2) from the viewpoint that the film quality can be more readily controlled. In case where the barrier layer is an inorganic oxide, a method is also preferred in which an inorganic substance is used as the evaporation source, and the evaporation source is evaporated to form a layer of the inorganic substance and thereafter the layer is left in air so as to be spontaneously oxidized. The method is preferred since the intended layer can be readily produced by the method.

Also preferably, an aluminium foil may be stuck to form a barrier layer. The thickness of the layer is preferably from 1 μm to 30 μm. When the thickness of the layer is at least 1 μm, then water could hardly penetrate into the polyester film while aged (under heat) and the film could hardly be hydrolyzed; and when at most 30 μm, then the barrier layer is not too thick and therefore would not cause denting of the film owing to the stress of the barrier layer.

### —Antifouling Layer—

Preferably, at least one of a fluororesin layer and a silicon (Si) resin layer is provided in the polyester film of the invention, as an antifouling layer therein. The fluororesin layer or the Si layer, when provided, attains antifouling and weather resistance enhancement. Concretely, it is desirable that the polyester film has a fluororesin coating layer as in JP-A2007-35694, 2008-28294, WO2007/063698.

It is also preferable to stick a fluororesin film of Tedlar (by DuPont) or the like to the polyester film.

Preferably, the thickness of the antifouling layer is from 1 μm to 50 μm, more preferably from 1 μm to 40 μm, even more preferably from 1 μm to 10 μm.

The antifouling layer may be a single layer or a multilayer laminate. Above all, it is preferable that the antifouling layer is composed of two layers and configured by a first antifouling layer and a second antifouling layer. In case where the layer is composed of multiple layers, the multiple layers may have the same composition or each may have a different composition, but preferably, the layers have the same composition.

Preferably, the antifouling layer contains a crosslinking agent. Preferred embodiments of the crosslinking agent may be the same as those used for the pigment in the above-mentioned reflection layer (colorant layer). Also preferably, the antifouling layer contains a pigment. Preferred embodiments of the pigment may be the same as those of the pigment used in the above-mentioned reflection layer (colorant layer).

### <Solar Cell Module>

The solar cell module of the invention contains the polyester film of the invention.

The solar cell module of the invention is so designed that a solar cell element capable of converting the light energy of sunlight into electric energy is sandwiched between a transparent substrate on which sunlight falls and the above-mentioned polyester film of the invention (back sheet for solar cell). The space between the substrate and the polyester film may be sealed up with a resin such as an ethylene/vinyl acetate copolymer or the like (so-called sealant).

The other parts than the solar cell module, the solar cell element and the back sheet are described, for example, in “Sunlight Power Generation System Constituent Materials” (edited by Eiichi Sugimoto, published by Kogyo Chosakai Publishing, 2008).

The transparent substrate may have light transmittance capable of transmitting sunlight therethrough, and may be suitably selected from light-transmitting substrates. From the viewpoint of power generation efficiency, those having high light transmittance are preferred, and preferred examples of the substrates of the type include glass substrates, transparent resins such as acrylic resins, etc.

As the solar cell element, herein usable is any one for various known solar cell elements, including, for example, silicon materials of single-crystal silicon, polycrystal silicon, amorphous silicon, etc.; III-V Group or II-VI Group compound semiconductor materials of copper-indium-gallium-selenium, copper-indium-selenium, cadmium-tellurium, gallium-arsenic, etc.

### EXAMPLES

The characteristics of the invention are described further concretely with reference to the following Examples.

In the following Examples, the material used, its amount and ratio, the details of the treatment and the treatment process may be suitably modified or changed not overstepping the spirit and the scope of the invention. Accordingly, the invention should not be limitatively interpreted by the Examples mentioned below.

Unless otherwise specifically indicated, “part” is by mass.

### Example 1

### 1. Production of Polyester Resin Composition

### —Step (A)—

4.7 tons of high-purity terephthalic acid and 1.8 tons of ethylene glycol were mixed to prepare a slurry, taking 90 minutes, and continuously supplied to a first esterification reactor at a flow rate of 3800 kg/h. Further, an ethylene glycol solution of a citric acid-chelated titanium complex with citric acid coordinated with Ti metal therein (VERTEC AC-420, by Johnson Massey) was continuously supplied into the reactor, and with stirring at an inner temperature of 250° C., these were reacted for a mean residence time of about 4.3 hours. In this state, the citric acid-chelated titanium complex was continuously so added that the Ti amount added could be 9 ppm in terms of the Ti element. In this state, the acid value of the obtained oligomer was 550 eq/ton.

The reaction product was transferred into a second esterification reactor, and with stirring and at an inner temperature of 250° C., these were reacted for a mean residence time of 1.2 hours to give an oligomer having an acid value of 180 eq/ton. The inside of the second esterification reactor was partitioned into 3 zones. From the second zone, an ethylene glycol solution of magnesium acetate was continuously supplied in such a manner that the amount of Mg added could be 75 ppm in terms of the element thereof, and subsequently from the third zone, an ethylene glycol solution of trimethyl phosphate was continuously supplied in such a manner that the amount of P added could be 65 ppm in terms of the element thereof.

The above process gave an esterified reaction product.

The ethylene glycol solution of trimethyl phosphate was prepared by adding trimethyl phosphate at 25° C. to ethylene glycol at 25° C. followed by stirring them at 25° C. for 2 hours.

(The content of the phosphorus compound in the solution was 3.8% by mass.)

### —Step (B)—

The esterified reaction product obtained in the step (A) was continuously supplied into a first polycondensation reactor, and with stirring at a reaction temperature of 270° C. and under an inner pressure of 20 Torr (2.67×10⁻³ MPa), this was polycondensed (for interesterification) for a mean residence time of about 1.8 hours.

Further, the reaction product was transferred from the first polycondensation reactor to a second polycondensation reactor, and with stirring therein at an inner temperature of 276° C. and under an inner pressure of 5 Torr (6.67×10⁻⁴ MPa), this was reacted (for interesterification) for a residence time of about 1.2 hours.

Next, the reaction product was transferred from the second polycondensation reactor to a third polycondensation reactor, and in this reactor at an inner temperature of 278° C. and under an inner pressure of 1.5 Torr (2.0×10⁻⁴ MPa), this was reacted (for interesterification) for a residence time of 1.5 hours to give a reaction product (polyethylene terephthalate (PET)).

Next, the obtained reaction product was jetted out into cold water like strands, and immediately cut into pellets of a polyester resin composition <cross section: major diameter, about 4 mm, minor diameter, about 2 mm; length: about 3 mm>. The pellets were dried in vacuum at 180° C., then put into the hopper of a single-screw kneading extruder equipped with a screw in the cylinder thereof, and extruded out to give a film.

### <Evaluation of Polyester Resin>

The obtained polyester resin was analyzed for the acid value (amount of terminal COOH group), according to the method mentioned below.

The results are shown in Table 1.

### (Acid Value of Resin (Amount of Terminal COOH Group))

According to the method described in H. A. Pohl, Anal. Chem. 26 (1954) 2145, the obtained polyester resin was analyzed for the amount of the terminal COOH group therein through titration. Concretely, the polyester resin was dissolved in benzyl alcohol at 205° C., a phenol red indicator was added thereto, and the solution was titered with a water/methanol/benzyl alcohol solution of sodium hydroxide.

As a result, the acid value of the obtained polyester resin was 22 eq/ton.

### <Synthesis of Epoxy Group-Containing Compound>

The following compound (1), which is a monofunctional glycidyl ether compound represented by the general formula (1), was synthesized by adding sodium hydroxide, tetrabutylammonium sulfate and epichlorohydrin to the starting alcohol.

The other epoxy group-containing compounds (2) to (8), (15) and (16) mentioned below were also synthesized according to the same method.

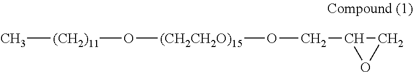

### (Determination of Water Content of Epoxy Group-Containing Compound)

According to the Karl-Fischer moisture titration method, the epoxy group-containing compound prepared in the above and added to the polyester resin composition as the starting material therein was analyzed for the water content thereof.

The results are shown in Table 1 below.

When the water content in the epoxy group-containing compound to be added in extrusion of the polyester resin composition is lower, the hydrolysis of the polyester resin in film formation can be prevented more. The water content in the epoxy group-containing compound is preferably at most 0.2%, more preferably at most 0.1%, even more preferably at most 0.05%.

### <Preparation of Polyester Resin Composition>

The polyester resin pellets produced through polymerization as above were dried to have a water content of at most 20 ppm, and then mixed with the compound (1) prepared in the above and with TPP-BB (phosphonium compound mentioned below) serving as a reaction promoter. The obtained composition is the polyester composition of Example 1.

TPP-BB (n-Butyltriphenylphosphonium Bromide, Phosphonium Compound)

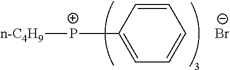

### 2. Production of Polyester Film

### —Extrusion Molding—

The polyester resin composition obtained in Example 1 was put into the hopper of a double-screw kneading extruder having a diameter of 50 mm, and melted and extruded at 280° C. The molten product (melt) was led to pass through a gear pump and a filter (having a pore size of 20 μm), and then extruded out onto a chill roll at 20° C. through a die to give an amorphous sheet. The extruded melt was airtightly adhered to the chill roll according to a static electricity imparting method.

### —Stretching—

The unstretched film that had been extruded out on the chill roll and solidified thereon according to the above-mentioned method was successively biaxially stretched according to the method mentioned below to give a polyester film having a thickness of 175 μm.

### <Stretching Method>

### (a) Longitudinal Stretching

The unstretched film was led to pass through two pairs of nip rolls each running at a different peripheral speed to thereby stretch the film in the longitudinal direction (traveling direction). The preheating temperature was 90° C., the stretching temperature was 90° C., the draw ratio in stretching was 3.5 times, and the stretching rate was 3000%/sec.

### (b) Lateral Stretching

The longitudinally-stretched film was laterally stretched under the condition mentioned below, using a tenter.

### <Condition>

Preheating temperature: 100° C.
Stretching temperature: 110° C.
Draw ratio in stretching: 3.9 times
Stretching rate: 70%/sec

### —Thermal Fixation, Thermal Relaxation—

Subsequently, the stretched film that had been stretched longitudinally and laterally was thermally fixed under the condition mentioned below. Further, after thermally fixed, the film was thermally relaxed under the condition mentioned below by reducing the tenter width.

### <Thermal Fixation Condition>

Thermal fixation temperature: 220° C.
Thermal fixation time: 2 seconds

### <Thermal Relaxation Condition>

Thermal relaxation temperature: (thermal fixation temperature—5° C.)
Thermal fixation rate: 2%

### —Winding—

After thermally fixed and thermally relaxed, both sides of the film were trimmed by 10 cm each. Subsequently, both sides of the film were knurled by a width of 10 mm each, and then the film was wound up under a tension of 25 kg/m. The width of the film was 1.5 m and the length of the rolled film was 2000 m.

As described above, a polyester film of Example 1 (hereinafter this may be referred to as “sample film”) was produced.

### <Evaluation of Polyester Film>

The polyester film obtained in Example 1 was analyzed for the acid value, the half-value period for retention of elongation at break (hr), the gel fraction and the volatility of the film, according to the methods mentioned below.

The obtained results are shown in Table 1 below.

### (Acid Value of Film (Amount of Terminal COOH))

The sample film was completely dissolved in a mixed solution of benzyl alcohol/chloroform (=2/3, by volume), and using phenol red as an indicator, the resulting solution was titered with a standard solution (0.025 N KOH/methanol mixed solution), and the terminal carboxyl group amount (eq/ton; terminal COOH amount) corresponding to the acid value of the film was derived from the titered value through computation.

(Half-Life Period of Retention of Elongation at Break (hr))

The half-life period of retention of elongation at break of the film was determined as follows: The polyester film obtained in Example 1 was stored (heat-treated) at 120° C. and at a relative humidity of 100%, and the storage time taken by the polyester film until the elongation at break (%) of the stored film could be 50% of the elongation at break (%) of the original film before storage was measured, and this indicates the half-life period of retention of elongation at break of the tested film.

The longer half-life period of retention of elongation at break of the tested film means that the polyester resin composition and the polyester film formed of the composition have better hydrolysis resistance.

### (Epoxy Retention)

The retention of the epoxy group-containing compound in the obtained polyester film (hereinafter this may be referred to as epoxy retention) was determined according to the method mentioned below.

5 g of the polyester film obtained by forming was added to 95 g of dichloromethane and stirred for 6 hours, and then the polyester film was removed through filtration. The resulting dichloromethane solution was concentrated under reduced pressure and the unreacted epoxy was extruded out. The molar number of the thus-extruded, epoxy group-containing compound was computed through NMR, and based on this, the epoxy group-containing compound retention (%) relative to the amount of the epoxy group-containing compound added in preparing the polyester resin composition was determined.

The obtained results are shown in Table 1 below.

The epoxy retention in the polyester film is preferably from 0.1% to 90%, more preferably from 10% to 60%. When the epoxy retention in the polyester film is not more than the upper limit of the above-mentioned preferred range, then the thermal stability of the epoxy group-containing compound could be lowered to such a degree that the reactivity of the compound with a polyester resin could be sufficiently increased, and therefore the acid value of the polyester resin could be thereby efficiently reduced. On the other hand, when the epoxy retention in the polyester film is not less than the lower limit of the preferred range, then the thermal stability of the epoxy group-containing compound could be increased so that the compound would not decompose before reacted with polyester, and therefore the acid value of the polyester resin could be thereby efficiently reduced.

### (Gel Fraction)

5 g of the obtained polyester film was dissolved in 95 g of HFIP (hexafluoroisopropanol) to prepare a 5 mas.% HFIP solution. The solution was filtered and dried at room temperature for 2 hours, then further dried in vacuum at 110° C. for 1 hour, and its weight was measured. The gel fraction of the film was computed according to the following formula.

Gel Fraction (%)=([filter weight after filtration (g)]−[filter weight before filtration (g)])/5(g)×100

Based on the data of the obtained gel fraction, the film was evaluated in point of the gel fraction thereof, according to the following criteria.

A: gel fraction ≦0.02%
B: 0.02% <gel fraction ≦0.1%
C: gel fraction >0.1%

The film having a high gel fraction is poorly stretchable or is poorly transparent.

### (Volatility)

The amount of the smoke generated from the die of the double-screw extruder was visually confirmed, and the volatility of the sample was evaluated according to the following criteria.

A: No smoke found.
B: A little smoke found.
C: Smoke found.

Those of high volatility are not good since the epoxy compound used adheres to the film surface to thereby worsen the film quality as generating offensive odor or forming fish eyes on the film surface.

### (Bleeding)

The obtained polyester film was visually checked for the presence or absence of bleeding out of the epoxy group-containing compound and the reaction promoter on the film surface.

A: No bleeding found on the film surface.
C: Bleeding found on the film surface.

### (Stretchability)

The biaxially stretched film was sandwiched between polarizers, and observed under cross-Nicol to evaluate the stretchability of the film.

A: Uniformly stretched.
C: Unevenly stretched.

### Examples 2 to 42, Comparative Examples 1 to 13

Films of other Examples and Comparative Examples were produced in the same manner as in Example 1 except that the polyester resin to be used, the acid value of the resin, the epoxy group-containing compound, the reaction promoter, the kneading temperature, the thermal fixation temperature and the film thickness were varied as in Table 1 below. In Examples 38 and 39, the buffer shown in Table 1 below was added prior to extrusion molding of the polyester resin composition, and then the polyester resin composition was extruded. In Examples 40 to 42, and Comparative Examples 5, 6 and 10 to 12, the polyester resin composition was extruded after the polyfunctional capping agent shown in Table 1 below was added thereto.

The structures of the epoxy group-containing compounds used in Examples and Comparative Examples are shown below. Here, the compounds (2) to (5) are those prepared by adding epichlorohydrin to Kao's Emulgen 103, 120, 123 and 150, respectively; the compounds (6) to (8) are those prepared by adding epichlorohydrin to Kao's Emulgen 306, 320 and 350, respectively; the compounds (15) and (16) are those prepared by adding epichlorohydrin to NOF's Unilube 50 MB-26 and Unilube 50 MB-11, respectively; and the compound (17) is Nagase Chemtex's EX-171. The compounds (9), (13) and (14) are polyfunctional capping agents not satisfying the above-mentioned general formula (1); and the compounds (10) to (12) are comparative epoxy group-containing compounds not satisfying the above-mentioned general formula (1).

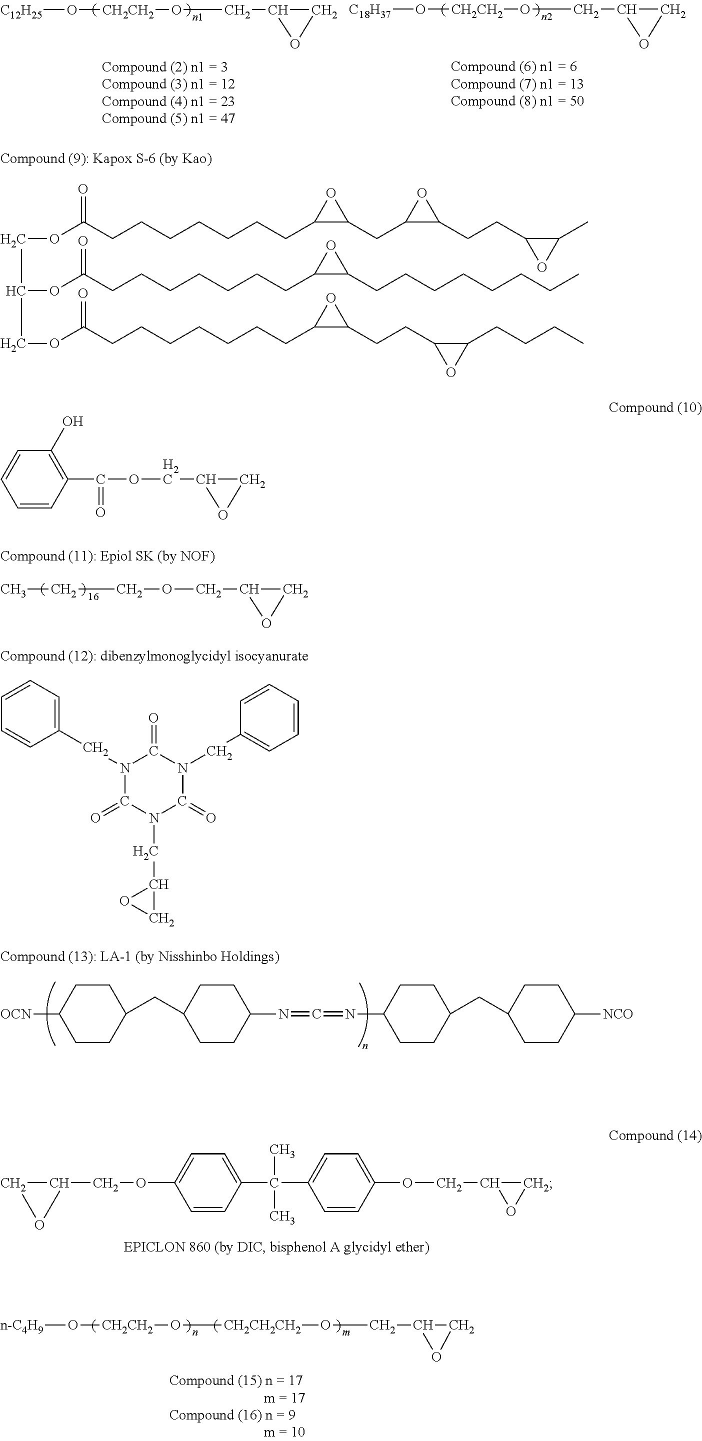

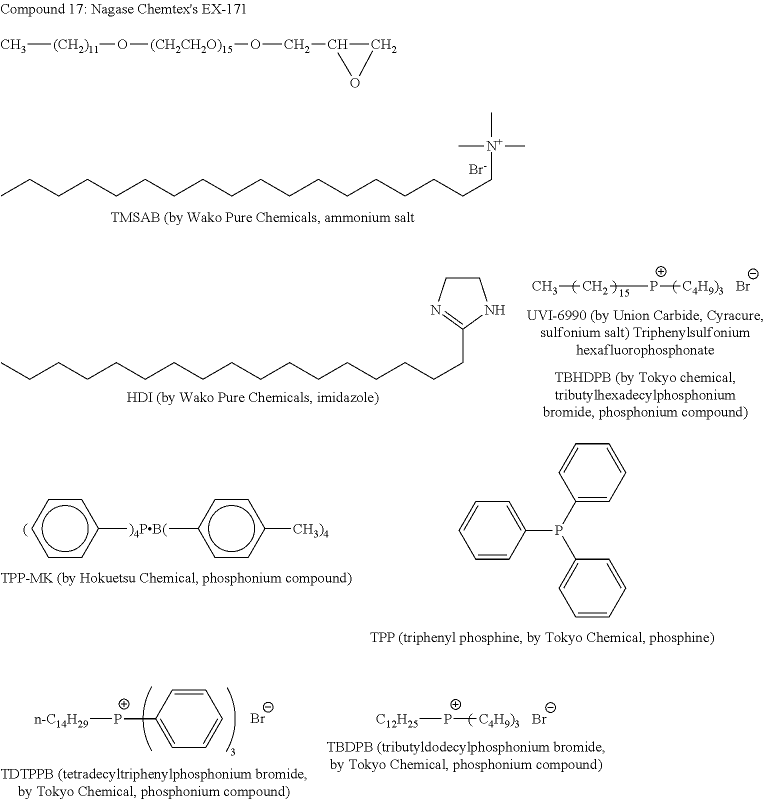

In Examples 7 to 9 and Comparative Example 2, the reaction product (polyethylene terephthalate (PET)) was obtained through reaction in the third polycondensation reactor, and then this was further processed for solid-phase polymerization according to the manner mentioned below, and thereafter pelletized.

Using a rotary vacuum polymerization reactor, the above PET was heated at 210° C. under a reduced pressure of 50 Pa for 30 hours. Subsequently, nitrogen gas at 25° C. was introduced into the vacuum polymerization reactor so that the pellets were cooled to 25° C. to give the polyester resin composition.

The polyester films obtained in Examples and Comparative Examples were evaluated in the same manner as in Example 1, and the results are shown in Table 1 below.

TABLE 1

| | | | Epoxy Group- | | | | Reaction | | Buffer/Poly-functional Capping | |
|---|---|---|---|---|---|---|---|---|---|---|
| | | | Containing Compound | | | | Promoter | | Agent | |
| | | | | | | amount | | amount | | amount |
| | Polyester Resin | | | epoxy | water | added | | added | | added |
| | | acid value | | retention | content | (% by | | (% by | | (% by |
| | type | (eq/ton) | type | (%) | (%) | mass) | type | mass) | type | mass) |
| Example 1 | PET | 22 | (1) | 32 | 0.2 | 3 | TPP-BB | 0.1 | | |
| Example 2 | PET | 22 | (1) | 36 | 0.2 | 3 | TPP-BB | 0.1 | | |
| Example 3 | PET | 22 | (1) | 40 | 0.2 | 3 | TPP-BB | 0.1 | | |
| Example 4 | PET | 22 | (1) | 42 | 0.2 | 3 | TPP-BB | 0.1 | | |
| Example 5 | PET | 22 | (1) | 28 | 0.2 | 1.5 | TPP-BB | 0.05 | | |
| Example 6 | PET | 22 | (1) | 25 | 0.2 | 1 | TPP-BB | 0.02 | | |
| Example 7 | solid-phase | 16 | (1) | 32 | 0.2 | 3 | TPP-BB | 0.1 | | |
| | polymerization | | | | | | | | | |
| | PET | | | | | | | | | |
| Example 8 | solid-phase | 16 | (1) | 32 | 0.2 | 1.5 | TPP-BB | 0.05 | | |
| | polymerization | | | | | | | | | |
| | PET | | | | | | | | | |
| Example 9 | solid-phase | 18 | (1) | 32 | 0.2 | 3 | TPP-BB | 0.1 | | |
| | polymerization | | | | | | | | | |
| | PET | | | | | | | | | |
| Example 10 | PET | 25 | (1) | 32 | 0.2 | 3 | TPP-BB | 0.1 | | |
| Example 11 | PET | 27 | (1) | 32 | 0.2 | 3 | TPP-BB | 0.1 | | |
| Example 12 | PET | 22 | (1) | 32 | 0.2 | 3 | TPP-BB | 0.1 | | |
| Example 13 | PET | 22 | (1) | 32 | 0.2 | 3 | TPP-BB | 0.1 | | |
| Example 14 | PEN | 22 | (1) | 45 | 0.2 | 3 | TPP-BB | 0.1 | | |
| Example 15 | PBT | 22 | (1) | 30 | 0.2 | 3 | TPP-BB | 0.1 | | |
| Example 16 | PET | 22 | (1) | 32 | 0.2 | 3 | TBHDPB | 0.1 | | |
| Example 17 | PET | 22 | (1) | 32 | 0.2 | 3 | TPP-MK | 0.1 | | |
| Example 18 | PET | 22 | (1) | 32 | 0.2 | 3 | TPP | 0.1 | | |
| Example 19 | PET | 22 | (1) | 32 | 0.2 | 3 | TPP-BB/ | 0.05/ | | |
| | | | | | | | TPP-MK | 0.05 | | |
| Example 20 | PET | 22 | (1) | 34 | 0.2 | 3 | TDTPPB | 0.1 | | |
| Example 21 | PET | 22 | (1) | 35 | 0.2 | 3 | TBDPB | 0.1 | | |
| Example 22 | PET | 22 | (2) | 33 | 0.2 | 3 | TPP-BB | 0.1 | | |
| Example 23 | PET | 22 | (3) | 32 | 0.2 | 3 | TPP-BB | 0.1 | | |
| Example 24 | PET | 22 | (4) | 31 | 0.2 | 3 | TPP-BB | 0.1 | | |
| Example 25 | PET | 22 | (5) | 32 | 0.2 | 3 | TPP-BB | 0.1 | | |
| Example 26 | PET | 22 | (6) | 33 | 0.2 | 3 | TPP-BB | 0.1 | | |
| Example 27 | PET | 22 | (7) | 33 | 0.2 | 3 | TPP-BB | 0.1 | | |
| Example 28 | PET | 22 | (8) | 32 | 0.2 | 3 | TPP-BB | 0.1 | | |
| Example 29 | PET | 22 | (15) | 32 | 0.2 | 3 | TPP-BB | 0.1 | | |
| Example 30 | PET | 22 | (16) | 32 | 0.2 | 3 | TPP-BB | 0.1 | | |
| Example 31 | PET | 16 | (1) | 35 | 0.2 | 1.5 | TBDPB | 0.05 | | |
| Example 32 | PET | 16 | (17) | 62 | 0.2 | 1.5 | TBDPB | 0.05 | | |
| Example 33 | PET | 16 | (1) | 36 | 0.1 | 1.5 | TBDPB | 0.05 | | |
| Example 34 | PET | 16 | (1) | 35 | 0.05 | 1.5 | TBDPB | 0.05 | | |
| Example 35 | PET | 16 | (1) | 35 | 0.02 | 1.5 | TBDPB | 0.05 | | |
| Example 36 | PET | 22 | (1) | 32 | 0.2 | 3 | TPP-BB | 0.1 | | |
| Example 37 | PET | 22 | (1) | 32 | 0.2 | 3 | TPP-BB | 0.1 | | |
| Example 38 | PET | 16 | (1) | 35 | 0.05 | 1.5 | TBDPB | 0.05 | sodium | 0.02 |
| | | | | | | | | | dihydrogenphosphate | |
| Example 39 | PET | 16 | (1) | 35 | 0.05 | 1.5 | TBDPB | 0.05 | sodium | 0.02/ |
| | | | | | | | | | dihydrogenphosphate/ | 0.03 |
| | | | | | | | | | phosphoric acid | |
| Example 40 | PET | 16 | (1) | 35 | 0.05 | 1.5 | TBDPB | 0.05 | Stabaxol P-400 | 0.5 |
| Example 41 | PET | 16 | (1) | 35 | 0.05 | 1.5 | TBDPB | 0.05 | (14) | 0.5 |
| Example 42 | PET | 16 | (1) | 35 | 0.05 | 1.5 | TBDPB | 0.05 | Epocross RPS-1005 | 0.5 |
| Comparative | PET | 22 | — | — | | — | — | — | | |
| Example 1 | | | | | | | | | | |
| Comparative | solid-phase | 16 | — | — | | — | — | — | | |
| Example 2 | polymerization | | | | | | | | | |
| | PET | | | | | | | | | |
| Comparative | PET | 22 | (1) | 5 | | 3 | — | — | | |
| Example 3 | | | | | | | | | | |
| Comparative | PET | 22 | — | — | | — | TPP-BB | 0.1 | | |
| Example 4 | | | | | | | | | | |
| Comparative | PET | 22 | — | — | | — | TPP-BB | 0.1 | (9) | 3 |
| Example 5 | | | | | | | | | | |
| Comparative | PET | 22 | (10) | — | | 3 | TPP | 0.1 | (9) | 3 |
| Example 6 | | | | | | | | | | |
| Comparative | PET | 22 | (10) | 27 | | 3 | TPP-BB | 0.1 | | |
| Example 7 | | | | | | | | | | |
| Comparative | PET | 22 | (11) | 28 | | 3 | TPP-BB | 0.1 | | |
| Example 8 | | | | | | | | | | |
| Comparative | PET | 22 | (12) | 5 | | 3 | TPP-BB | 0.1 | | |
| Example 9 | | | | | | | | | | |
| Comparative | PET | 22 | — | — | | — | — | — | (13) | 3 |
| Example 10 | | | | | | | | | | |
| Comparative | PET | 22 | — | 28 | | — | TPP-BB | 0.1 | (14) | 3 |
| Example 11 | | | | | | | | | | |
| Comparative | PET | 22 | (11) | 28 | | — | TPP-BB | 0.1 | (14) | 3 |
| Example 12 | | | | | | | | | | |
| Comparative | PET | 22 | (12) | 4 | | 3 | triphenyl | 0.1 | | |
| Example 13 | | | | | | | phosphate | | | |

| | | | | Test Items | | | | | |
|---|---|---|---|---|---|---|---|---|---|
| | | | | | half-life | | | | |
| | | Thermal | | | period of | | | | |
| | Kneading | Fixation | Film | film acid | elongation | | | | |
| | Temperature | Temperature | Thickness | value | at break | | | | stretching |
| | (° C.) | (° C.) | (μm) | (eq/ton) | (hr) | gel | volatility | bleeding | unevenness |
| Example 1 | 280 | 220° C. | 175 | 12 | 95 | A | A | A | A |
| Example 2 | 290 | 220° C. | 175 | 13 | 90 | A | A | A | A |
| Example 3 | 300 | 220° C. | 175 | 14 | 85 | A | A | A | A |
| Example 4 | 310 | 220° C. | 175 | 15 | 85 | A | A | A | A |
| Example 5 | 280 | 220° C. | 175 | 14 | 85 | A | A | A | A |
| Example 6 | 280 | 220° C. | 175 | 15 | 85 | A | A | A | A |
| Example 7 | 280 | 220° C. | 175 | 9 | 115 | A | A | A | A |
| Example 8 | 280 | 220° C. | 175 | 12 | 95 | A | A | A | A |
| Example 9 | 280 | 220° C. | 175 | 11 | 105 | A | A | A | A |
| Example 10 | 280 | 220° C. | 175 | 15 | 80 | A | A | A | A |
| Example 11 | 280 | 220° C. | 175 | 17 | 78 | A | A | A | A |
| Example 12 | 280 | 220° C. | 75 | 12 | 95 | A | A | A | A |
| Example 13 | 280 | 220° C. | 300 | 12 | 95 | A | A | A | A |
| Example 14 | 320 | 220° C. | 175 | 12 | 150 | A | A | A | A |
| Example 15 | 260 | 220° C. | 175 | 12 | 95 | A | A | A | A |
| Example 16 | 280 | 220° C. | 175 | 12 | 95 | A | A | A | A |
| Example 17 | 280 | 220° C. | 175 | 12 | 95 | A | A | A | A |
| Example 18 | 280 | 220° C. | 175 | 12 | 95 | A | A | A | A |
| Example 19 | 280 | 220° C. | 175 | 12 | 95 | A | A | A | A |
| Example 20 | 280 | 220° C. | 175 | 11 | 100 | A | A | A | A |
| Example 21 | 280 | 220° C. | 175 | 11 | 100 | A | A | A | A |
| Example 22 | 280 | 220° C. | 175 | 9 | 115 | A | B | A | A |
| Example 23 | 280 | 220° C. | 175 | 11 | 100 | A | B | A | A |
| Example 24 | 280 | 220° C. | 175 | 12 | 95 | A | A | A | A |
| Example 25 | 280 | 220° C. | 175 | 13 | 90 | A | A | A | A |
| Example 26 | 280 | 220° C. | 175 | 10 | 110 | A | B | A | A |
| Example 27 | 280 | 220° C. | 175 | 12 | 95 | A | A | A | A |
| Example 28 | 280 | 220° C. | 175 | 13 | 90 | A | A | A | A |
| Example 29 | 280 | 220° C. | 175 | 13 | 90 | A | A | A | A |
| Example 30 | 280 | 220° C. | 175 | 12 | 95 | A | A | A | A |
| Example 31 | 280 | 220° C. | 175 | 10 | 110 | A | A | A | A |
| Example 32 | 280 | 220° C. | 175 | 18 | 79 | A | A | A | A |
| Example 33 | 280 | 220° C. | 175 | 9 | 115 | A | A | A | A |
| Example 34 | 280 | 220° C. | 175 | 8 | 120 | A | A | A | A |
| Example 35 | 280 | 220° C. | 175 | 8 | 130 | A | A | A | A |
| Example 36 | 280 | 200° C. | 175 | 12 | 105 | A | A | A | A |
| Example 37 | 280 | 190° C. | 175 | 12 | 110 | A | A | A | A |
| Example 38 | 280 | 200° C. | 175 | 8 | 140 | A | A | A | A |
| Example 39 | 280 | 200° C. | 175 | 8 | 150 | A | A | A | A |
| Example 40 | 280 | 200° C. | 175 | 5 | 160 | A | A | A | A |
| Example 41 | 280 | 200° C. | 175 | 5 | 160 | A | A | A | A |
| Example 42 | 280 | 200° C. | 175 | 5 | 160 | A | A | A | A |
| Comparative | 280 | | 175 | 24 | 60 | A | A | A | A |
| Example 1 | | | | | | | | | |
| Comparative | 280 | | 175 | 20 | 70 | A | A | A | A |
| Example 2 | | | | | | | | | |
| Comparative | 280 | | 175 | 22 | 65 | A | A | C | C |
| Example 3 | | | | | | | | | |
| Comparative | 280 | | 175 | 25 | 50 | A | A | A | A |
| Example 4 | | | | | | | | | |
| Comparative | 280 | | 175 | 22 | 65 | B | A | C | A |
| Example 5 | | | | | | | | | |
| Comparative | 280 | | 175 | 22 | 65 | B | C | C | A |
| Example 6 | | | | | | | | | |
| Comparative | 280 | | 175 | 15 | 80 | A | C | C | A |
| Example 7 | | | | | | | | | |
| Comparative | 280 | | 175 | 12 | 70 | A | C | C | A |
| Example 8 | | | | | | | | | |
| Comparative | 280 | | 175 | 20 | 50 | A | B | C | A |
| Example 9 | | | | | | | | | |
| Comparative | 280 | | 175 | 12 | 80 | C | A | C | A |
| Example 10 | | | | | | | | | |
| Comparative | 280 | | 175 | 12 | 95 | C | A | C | A |
| Example 11 | | | | | | | | | |
| Comparative | 280 | | 175 | 12 | 95 | C | A | C | A |
| Example 12 | | | | | | | | | |
| Comparative | 280 | | 175 | 20 | 50 | A | B | C | A |
| Example 13 | | | | | | | | | |

From the results shown in Table 1, it is known that the polyester films obtained in Examples (polyester films of Examples) all have a long half-life period of retention of elongation at break and excellent in hydrolysis resistance as compared with those of Comparative Examples. In addition, it is also known that the polyester films of Examples all have a low gel fraction and low volatility.

This means that the polyester films for solar cells to which the polyester films of Examples are applied have excellent weather resistance, and the solar cell power generation modules equipped with the polyester film for solar cells secure stable power generation performance for a long period of time.

On the other hand, from Comparative Examples 1 and 2, it is known that the acid value of the films not containing a monofunctional glycidyl ether compound represented by the general formula (1) increases as compared with the acid value of the resin to constitute the film and, in addition, the half-life period of elongation at break of the films is short and the hydrolysis resistance of the films is poor. From

Comparative Example 3, it is known that, when only the monofunctional glycidyl ether compound having a specific structure is added, then the half-life period of elongation at break of the film is short and the hydrolysis resistance of the film is poor. In addition, the case involved problems of bleeding and stretching unevenness. From Comparative Example 4, it is known that, when the film does not contain an epoxy group-containing compound as a hydrolysis-resisting agent, then the half-life period of elongation at break of the film is short and the hydrolysis resistance of the film is poor. From Comparative Examples 5 to 13, it is known that, when a comparative epoxy group-containing compound not falling within the scope of the structure of the general formula (1) in the invention is used, then the films could not satisfy all the requirements of long half-life period of elongation at break, low gel fraction and low volatility.

### 3. Production of Back Sheet for Solar Cells

Using the polyester films produced in Examples 1 to 42 and Comparative Examples 1 to 13, back sheets for solar cells were produced.

(i) A reflection layer and (ii) an easy adhesion layer mentioned below were formed in that order on one surface of the polyester film produced in Examples 1 to 42 and Comparative Examples 1 to 13.

### (i) Reflection Layer (Colorant Layer)

First, the ingredients mentioned below were mixed, and dispersed for 1 hour with a Dyno mill-type disperser to prepare a pigment dispersion.

<Formulation of Pigment Dispersion>

| | |
|---|---|
| Titanium dioxide (Taipake R780-2, by Ishihara Sangyo, solid | 39.9 parts |
| content 100% by mass) | |
| Polyvinyl alcohol (PVA-105, by Kuraray, solid content 10%) | 8.0 parts |
| Surfactant (Demole EP, by Kao, solid content 25%) | 0.5 parts |
| Distilled water | 51.6 parts |

Next, using the obtained pigment dispersion, the ingredients mentioned below were mixed to prepare a coating liquid for reflection layer formation.

<Formulation of Coating Liquid for Reflection Layer Formation>

| | |
|---|---|
| Above pigment dispersion | 71.4 parts |
| Aqueous dispersion of polyacrylic resin (binder: Jurymer | 17.1 parts |
| ET-410, by Ninon Junyaku, solid content 30% by mass) | |
| Polyoxyalkylene alkyl ether (Naroacty CL95, by Sanyo | 2.7 parts |
| Chemical, solid content 1% by mass) | |
| Oxazoline compound (crosslinking agent) (Epocross | 1.8 parts |
| WS-700, by Nippon Shokubai, solid content 25% by mass) | |
| Distilled water | 7.0 parts |

The coating liquid for reflection layer formation that had been obtained in the above was applied onto the sample film, using a bar coater, and dried at 180° C. for 1 minute to form a reflection layer (white layer) (i) having a titanium dioxide coating amount of 6.5 g/m².

### (ii) Easy Adhesion Layer

The ingredients mentioned below were mixed to prepare a coating liquid for easy adhesion layer, and this was applied onto the reflection layer (i) in order that the binder coating amount could be 0.09 g/m². Subsequently, this was dried at 180° C. for 1 minute to form an easy adhesion layer (ii).

<Composition of Coating Liquid for Easy Adhesion Layer>

| | |
|---|---|
| Aqueous dispersion of polyolefin resin (binder: Chemipearl | 5.2 parts |
| S75N, by Mitsui Chemical, solid content 24% by mass) | |
| Polyoxyalkylene alkyl ether (Naroacty CL95, by Sanyo | 7.8 parts |
| Chemical Industry, solid content 1% by mass) | |
| Oxazoline compound (Epocross WS-700, by Nippon | 0.8 parts |
| Shokubai, solid content 25% by mass) | |
| Aqueous dispersion of silica fine particles (Aerosil | 2.9 parts |
| OX-50, by Nippon Aerosil, solid content 10% by mass) | |
| Distilled water | 83.3 parts |

Next, the following undercoat layer (iii), barrier layer (iv) and antifouling layer (v) were applied onto the other surface of the polyester film opposite to the surface thereof coated with the reflection layer (i) and the easy adhesion layer (ii), in that order from the side of the polyester film.

(iii) Undercoat Layer

The following ingredients were mixed to prepare a coating liquid for undercoat layer. The coating liquid was applied onto the polyester film and dried at 180° C. for 1 minute to form an undercoat layer (dry coating amount: about 0.1 g/m²).

<Composition of Coating Liquid for Undercoat Layer>

| | |
|---|---|
| Polyester resin (Vylonal MD-1200, by Toyobo, solid | 1.7 parts |
| content 17% by mass) | |
| Polyester resin (Pesresin A-520, by Takamatsu Yushi, | 3.8 parts |
| solid content 30% by mass) | |
| Polyoxyalkylene alkyl ether (Naroacty CL95, by Sanyo | 1.5 parts |
| Chemical Industry, solid content 1% by mass) | |
| Carbodiimide compound (Carbodilite V-02-L2, by | 1.3 parts |
| Nisshinbo, solid content 10% by mass) | |
| Distilled water | 91.7 parts |

### (iv) Barrier Layer

Subsequently, a vapor deposition film of silicon oxide having a thickness of 800 angstroms was formed on the surface of the formed undercoat layer, according to the vapor deposition condition mentioned below thereby forming a barrier layer.

### <Vapor Deposition Condition>

Blend ratio of reaction gases (unit: slm):

hexamethyldisiloxane/oxygen gas/helium=1/10/10

Vacuum degree in vacuum chamber: 5.0×10-6 mbar
Vacuum degree in vapor deposition chamber: 6.0×10-2 mbar
Cooling electrode drum supply power: 20 kW
Film traveling speed: 80 m/min

### (v) Antifouling Layer

As shown below, coating liquids for forming first and second antifouling layers were prepared. The coating liquid for first antifouling layer and the coating liquid for second antifouling layer were applied onto the barrier layer in that order, thereby forming an antifouling layer having a two-layer configuration.

### <First Antifouling Layer>

### Preparation of Coating Liquid for First Antifouling Layer

The following ingredients were mixed to prepare a coating liquid for first antifouling layer.

<Composition of Coating Liquid>

| | |
|---|---|
| Ceranate WSA1070 (by DIC) | 45.9 parts |
| Oxazoline compound (crosslinking agent) (Epocross WS-700, | 7.7 parts |
| by Nippon Shokubai, solid content 25% by mass) | |
| Polyoxyalkylene alkyl ether (Naroacty CL95, by Sanyo | 2.0 parts |
| Chemical Industry, solid content 1% by mass) | |
| Pigment dispersion used in reflection layer | 33.0 parts |
| Distilled water | 11.4 parts |

### —Formation of First Antifouling Layer—

The obtained coating liquid was applied onto the barrier layer in such a manner that the binder coating amount could be 3.0 g/m², and dried at 180° C. for 1 minute to form a first antifouling layer.

### —Preparation of Coating Liquid for Second Antifouling Layer—

The following ingredients were mixed to prepare a coating liquid for second antifouling layer.

<Composition of Coating Liquid>

| | |
|---|---|
| Fluorine-containing binder: Obbligato (by AGC Coat-Tech) | 45.9 parts |
| Oxazoline compound (Epocross WS-700, by Nippon | 7.7 parts |
| Shokubai, solid content 25% by mass) | |
| Polyoxyalkylene alkyl ether (Naroacty CL95, by Sanyo | 2.0 parts |
| Chemical Industry, solid content 1% by mass) | |
| Pigment dispersion prepared for the above reflection layer | 33.0 parts |
| Distilled water | 11.4 parts |

### —Formation of Second Antifouling Layer—

The prepared coating liquid for second antifouling layer was applied onto the first antifouling layer formed on the barrier layer, in such a manner that the binder coating amount could be 2.0 g/m², and dried at 180° C. for 1 minute to form a second antifouling layer.

In the manner as above, back sheets for solar cells of Examples and Comparatives were produced, each having the reflection layer and the easy adhesion layer on one side of the polyester film and having the undercoat layer, the barrier layer and the antifouling layer on the other side thereof.

### (Evaluation of Adhesiveness of Back Sheet)

The back sheets of Examples and Comparative Examples produced as above were stored (for heat treatment) under the condition at 120° C. and at a relative humidity of 100%. After thus stored, the back sheets were rubbed back and forth for a total of 10 times with BEMCOT, and evaluated for the adhesiveness thereof according to the following criteria.

A: No peeling.

B: Partly peeled.

C: Entirely peeled.

D: Peeled before rubbing.

Those with less peeling are better in that the adhesiveness of the polyester resin composition and the polyester film formed of the composition to the other layers is excellent.

The adhesiveness evaluation results are shown in Table 2 below.

TABLE 2

| | Adhesiveness of Back Sheet |
|---|---|
| Example 1 | A |
| Example 2 | A |
| Example 3 | A |
| Example 4 | A |
| Example 5 | A |
| Example 6 | A |
| Example 7 | A |
| Example 8 | A |
| Example 9 | A |
| Example 10 | A |
| Example 11 | A |
| Example 12 | A |
| Example 13 | A |
| Example 14 | A |
| Example 15 | A |
| Example 16 | A |
| Example 17 | A |
| Example 18 | A |
| Example 19 | A |
| Example 20 | A |
| Example 21 | A |
| Example 22 | A |
| Example 23 | A |
| Example 24 | A |
| Example 25 | A |
| Example 26 | A |
| Example 27 | A |
| Example 28 | A |
| Example 29 | A |
| Example 30 | A |
| Example 31 | A |
| Example 32 | A |
| Example 33 | A |
| Example 34 | A |
| Example 35 | A |
| Example 36 | A |
| Example 37 | A |
| Example 38 | A |
| Example 39 | A |
| Example 40 | A |
| Example 41 | A |
| Example 42 | A |
| Comparative Example 1 | B |
| Comparative Example 2 | C |
| Comparative Example 3 | B |
| Comparative Example 4 | B |
| Comparative Example 5 | B |
| Comparative Example 6 | B |
| Comparative Example 7 | D |
| Comparative Example 8 | D |
| Comparative Example 9 | B |
| Comparative Example 10 | D |
| Comparative Example 11 | D |
| Comparative Example 12 | D |
| Comparative Example 13 | C |

As in the above Table 2, the back sheets for solar cells of Examples 1 to 42 exhibited high adhesiveness though the film acid value was small. On the other hand, the back sheets for solar cells of Comparative Examples 7, 8 and 10 to 12, all having a low film acid value, had low adhesiveness and readily peeled. The back sheets for solar cells of Comparative Examples 1 to 6, 9 and 13 were inferior to the back sheets for solar cells of Examples 1 to 42 in point of the adhesiveness thereof, though the film acid value of the former was higher than that of the latter.

### 4. Production of Solar Cell

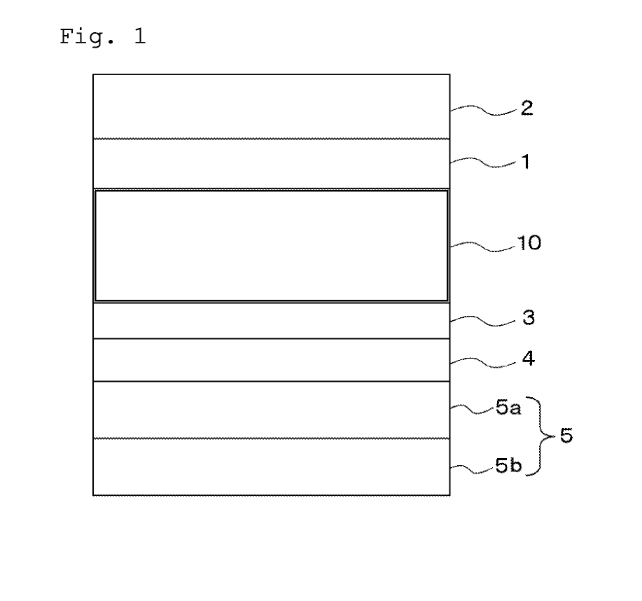

The back sheet produced in the manner as above was stuck to a transparent filler so as to have the configuration shown in FIG. 1 in JP-A 2009-158952, thereby producing a solar cell power generation module. In this, the back sheet was so stuck thereto that the easy adhesion layer thereof could be in contact with the transparent filler with a solar cell element buried therein.

### 5. Outward Evaluation of Solar Cell

The adhesiveness of the polyester film of Comparative Examples 7 to 8, and 10 to 12 was poor, and therefore when the film was stuck to the solar cell element, it partly peeled to cause failures. On the other hand, the adhesiveness of the polyester film of Examples 1 to 42 and Comparative Examples 1 to 6, 9 and 13 was good, and by using the film, there were provided good solar cells with no defect.

### INDUSTRIAL APPLICABILITY

The polyester film of the invention is favorably used for, for example, a back sheet (sheet to be arranged on one side of a solar cell element opposite to the side thereof to receive the incident light falling thereon, or that is, the back sheet of a solar cell) for constituting solar cell modules.

While the present invention has been described in detail and with reference to specific embodiments thereof, it will be apparent to one skilled in the art that various changes and modifications can be made therein without departing from the spirit and scope thereof.

The present disclosure relates to the subject matter contained in International Application No. PCT/JP2011/070259, filed Sep. 6, 2011; Japanese Application No. 2010-208015, filed Sep. 16, 2010; and Japanese Application No. 2011-114384, filed May 23, 2011, the contents of which are expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A polyester film containing (A) a polyester, (B) a monofunctional glycidyl ether compound represented by the following general formula (1), and (C) a reaction promoter: 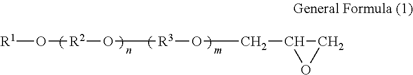
wherein R¹ represents an aliphatic hydrocarbon group having 1 or more carbon atoms, R² and R³ each independently represent an alkylene group having 2 or more carbon atoms provided that R² and R³ differ from each other, n indicates an integer of 1 or more, and m indicates an integer of 0 or more.

2. The polyester film according to claim 1, wherein R¹ in the general formula (1) is a linear aliphatic hydrocarbon group having from 4 to 25 carbon atoms.

3. The polyester film according to claim 1, wherein the monofunctional glycidyl ether compound represented by the general formula (1) has the structure represented by the following formula (2): 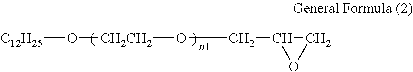
wherein n1 indicates an integer of 1 or more.

4. The polyester film according to claim 1, wherein the monofunctional glycidyl ether compound represented by the general formula (1) has the structure represented by the following formula (3): 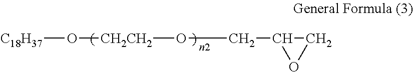
wherein n2 indicates an integer of 1 or more.

5. The polyester film according to claim 1, wherein R² and R³ in the general formula (1) each independently represent an alkylene group having 2 to 4 carbon atoms.

6. The polyester film according to claim 1, wherein m in the general formula (1) is an integer of 1 or more.

7. The polyester film according to claim 1, wherein the reaction promoter is a phosphonium compound or a phosphine.

8. The polyester film according to claim 1, wherein n in the general formula (1) is from 2 to 100.

9. The polyester film according to claim 1, wherein R² in the general formula (1) is an ethylene group.

10. The polyester film according to claim 1, wherein R¹ in the general formula (1) is an aliphatic hydrocarbon group having from 8 to 20 carbon atoms.

11. The polyester film according to claim 1, wherein the molecular weight of the monofunctional glycidyl ether compound represented by the general formula (1) is 800 or more.

12. The polyester film according to claim 1, wherein the acid value of the polyester is at most 25 eq/ton.

13. The polyester film according to claim 1, wherein the polyester is polyethylene terephthalate.

14. The polyester film according to claim 1, wherein the polyester is produced through solid-phase polymerization.

15. The polyester film according to claim 1, which is biaxially stretched.

16. The polyester film according to claim 1, which has an acid value of at most 15 eq/ton.

17. The polyester film according to claim 1, which, when stored in an atmosphere at a temperature of 120° C. and a relative humidity of 100%, takes a storage time of at least 75 hours for which the elongation at break of the film after storage reaches 50% of the elongation at break thereof before storage.

18. The polyester film according to claim 1, which contains a buffer.

19. A back sheet for solar cells, which contains a polyester film containing (A) a polyester, (B) a monofunctional glycidyl ether compound represented by the following general formula (1), and (C) a reaction promoter: 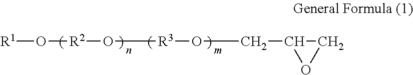
wherein R¹ represents an aliphatic hydrocarbon group having 1 or more carbon atoms, R² and R³ each independently represent an alkylene group having 2 or more carbon atoms provided that R² and R³ differ from each other, n indicates an integer of 1 or more, and m indicates an integer of 0 or more.

20. A solar cell power generation module, which contains a polyester film containing (A) a polyester, (B) a monofunctional glycidyl ether compound represented by the following general formula (1), and (C) a reaction promoter: 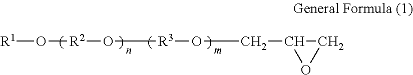
wherein R¹ represents an aliphatic hydrocarbon group having 1 or more carbon atoms, R² and R³ each independently represent an alkylene group having 2 or more carbon atoms provided that R² and R³ differ from each other, n indicates an integer of 1 or more, and m indicates an integer of 0 or more.
